(19) United States
(12) Patent Application Publication
(10) Pub. No.: US 2025/0077925 A1
(43) Pub. Date: Mar. 6, 2025

(54) CALIBRATIONS DURING TANDEM EXECUTION OF QUANTUM CIRCUITS

(71) Applicant: IonQ, Inc., College Park, MD (US)

(72) Inventors: Neal Carden PISENTI, Portland, OR (US); John King GAMBLE, Redmond, WA (US); David Paul CAMPAGNA, Westminster, CO (US)

(21) Appl. No.: 18/620,642

(22) Filed: Mar. 28, 2024

Related U.S. Application Data
(60) Provisional application No. 63/492,741, filed on Mar. 28, 2023.
(60) Provisional application No. 63/613,462, filed on Dec. 21, 2023.

(51) Int. Cl. G06N 10/40; G01R 31/28

(52) U.S. Cl. CPC G06N 10/40; G01R 31/282

(57) ABSTRACT

Aspects of the present disclosure relate generally to systems and methods for use in the implementation and/or operation of quantum information processing (QIP) systems, and more particularly, calibrations during tandem execution of quantum circuits.

### CROSS-REFERENCE TO RELATED APPLICATION

This application claims the benefit of and priority to U.S. Provisional Patent Application No. 63/492,741, filed Mar. 28, 2023, and U.S. Provisional Patent Application No. 63/613,462, filed Dec. 21, 2023, the contents of which applications are hereby incorporated by reference herein in their entireties.

### BACKGROUND

Aspects of the present disclosure relate generally to systems and methods for use in the implementation, operation, and/or use of quantum information processing (QIP) systems.

Trapped atoms are one of the leading implementations for quantum information processing or quantum computing. Atomic-based qubits may be used as quantum memories, as quantum gates in quantum computers and simulators, and may act as nodes for quantum communication networks. Qubits based on trapped atomic ions enjoy a rare combination of attributes. For example, qubits based on trapped atomic ions have very good coherence properties, may be prepared and measured with nearly 100% efficiency, and are readily entangled with each other by modulating their Coulomb interaction with suitable external control fields such as optical or microwave fields. These attributes make atomic-based qubits attractive for extended quantum operations such as quantum computations or quantum simulations.

It is therefore important to develop new techniques that improve the design, fabrication, implementation, control, and/or functionality of different QIP systems used as quantum computers or quantum simulators, and particularly for those QIP systems that handle operations based on atomic-based qubits.

### SUMMARY

The following presents a simplified summary of one or more aspects to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detailed description that is presented later.

This disclosure recognizes and addresses, among other technical challenges, the issue of calibration in QIP systems (or quantum computers). This disclosure describes various aspects that, individually or in combination, permit optimizing the qubit resources used for the calibration of a QIP system. More specifically, yet not exclusively, this disclosure provides a general framework for determining under what circumstances multiple tasks can be executed in tandem, where the multiple tasks include purely calibration tasks, purely computational tasks, or a combination of calibration tasks and computational tasks.

In an aspect of this disclosure, a computer-implemented method is provided. The computer-implemented method includes obtaining a production quantum circuit corresponding to a defined n-qubit computation, the production quantum circuit defined in a qubit register having one or more first qubits and executable in quantum hardware having multiple second qubits including the one or more first qubits; identifying a subset of the multiple second qubits that excludes the one or more first qubits; allocating at least one particular qubit of the subset for execution of a calibration quantum circuit; and causing the quantum hardware to execute the production quantum circuit and the calibration quantum circuit during a measurement cycle. As is used in this disclosure, the terminology “production quantum circuit” refers to a computation quantum circuit that is configured and executed for purposes other than calibration. Accordingly, in this disclosure, the terminology “production quantum circuit” and “computation quantum circuit” are used interchangeably, and both refer to a quantum circuit that is configured and/or executed for purposes different from the purpose of a calibration quantum circuit.

In another aspect of this disclosure, a computer-implemented method is provided. The computer-implemented method includes obtaining a first quantum circuit; obtaining a second quantum circuit; determining that the first quantum circuit and the second quantum circuit are executable during a common measurement cycle in quantum hardware having multiple qubits; generating an executable quantum circuit by combining the first quantum circuit and the second quantum circuit; and causing the quantum hardware to execute the executable quantum circuit during the common measurement cycle.

In other aspects of this disclosure classical computing systems are provided to implement the foregoing computer-implemented method. In yet other aspects of this disclosure, computer program products also are provided. The computer-program products have computer-executable instructions stored thereon that, in response to execution by a classical processor, causes a QIP system to perform the foregoing computer-implemented method.

In some aspects, the technologies disclosed herein relate to a quantum information processing (QIP) system including: at least one processor; and at least one memory devices storing processor-executable instructions that, in response to being executed by the at least one processor, cause the QIP system at least to: obtain a production quantum circuit corresponding to a defined n-qubit computation, the production quantum circuit defined in a qubit register having one or more first qubits and executable in quantum hardware having multiple second qubits including the one or more first qubits; identify a subset of the multiple second qubits that excludes the one or more first qubits; allocate at least one particular qubit of the subset for execution of a calibration quantum circuit; and cause the quantum hardware to execute the production quantum circuit and the calibration quantum circuit during a measurement cycle.

In some aspects, the technologies disclosed herein relate to a computer-implemented method for automatically identifying quantum circuits executable in tandem, the method including: testing, across a sampling of quantum circuit instances, validity of a hypothesis that execution of a pair of second quantum circuits yields a same result irrespective of order of execution of the pair of second quantum circuits; and generating, based on the testing, heuristics that identify a particular pair of quantum circuits as being executable in tandem. In some aspects, the technologies disclosed herein relate to a non-transitory computer readable medium containing processor-executable instructions that, in response to being executed by at least one processor, individually or in combination, cause a classical computing system to perform operations including: testing, across a sampling of quantum circuit instances, validity of a hypothesis that execution of a pair of second quantum circuits yields a same result irrespective of order of execution of the pair of second quantum circuits; and generating, based on the testing, heuristics that identify a particular pair of quantum circuits as being executable in tandem.

In some aspects, the technologies disclosed herein relate to a classical computing system including: at least one processor; and at least one memory devices storing processor-executable instructions that, in response to being executed by the at least one processor, individually or in combination, cause the classical computing system at least to: test, across a sampling of quantum circuit instances, validity of a hypothesis that execution of a pair of second quantum circuits yields a same result irrespective of order of execution of the pair of second quantum circuits; and generate, based on the testing, heuristics that identify a particular pair of quantum circuits as being executable in tandem.

In some aspects, the technologies disclosed herein relate to a quantum information processing (QIP) system including: at least one processor; and at least one memory device storing processor-executable instructions that, in response to being executed by the at least one processor, cause the QIP system at least to: test, across a sampling of quantum circuit instances, validity of a hypothesis that execution of a pair of second quantum circuits yields a same result irrespective of order of execution of the pair of second quantum circuits; and generate, based on the testing, heuristics that identify a particular pair of quantum circuits as being executable in tandem.

In some aspects, the technologies disclosed herein relate to a computer-implemented method for efficiently utilizing qubit resources to execute quantum circuits in a quantum hardware, the method including: determining that a first quantum circuit of the quantum circuits and a second quantum circuit of the quantum circuits are executable in tandem; combining the first quantum circuit and the second quantum circuit into a common quantum circuit for execution on the quantum hardware during a common measurement cycle; causing the quantum hardware to execute the first quantum circuit and the second quantum circuit in the common measurement cycle; and separating, upon or after termination of the common measurement cycle, a first result corresponding to execution of the first quantum circuit and a second result corresponding to execution of the second quantum circuit.

In some aspects, the technologies disclosed herein relate to a non-transitory computer readable medium containing processor-executable instructions that, in response to being executed by at least one processor, individually or in combination, cause a computing system to perform operations including: determining that a first quantum circuit of the quantum circuits and a second quantum circuit of the quantum circuits are executable in tandem; combining the first quantum circuit and the second quantum circuit into a common quantum circuit for execution on the quantum hardware during a common measurement cycle; causing the quantum hardware to execute the first quantum circuit and the second quantum circuit in the common measurement cycle; and separating, upon or after termination of the common measurement cycle, a first result corresponding to execution of the first quantum circuit and a second result corresponding to execution of the second quantum circuit.

In some aspects, the technologies disclosed herein relate to a classical computing system including: at least one processor; and at least one memory devices storing processor-executable instructions that, in response to being executed by the at least one processor, individually or in combination, cause the classical computing system at least to: determine that a first quantum circuit of the quantum circuits and a second quantum circuit of the quantum circuits are executable in tandem; combine the first quantum circuit and the second quantum circuit into a common quantum circuit for execution on the quantum hardware during a common measurement cycle; cause the quantum hardware to execute the first quantum circuit and the second quantum circuit in the common measurement cycle; and separate, upon or after termination of the common measurement cycle, a first result corresponding to execution of the first quantum circuit and a second result corresponding to execution of the second quantum circuit.

In some aspects, the technologies disclosed herein relate to a quantum information processing (QIP) system including: at least one processor; and at least one memory devices storing processor-executable instructions that, in response to being executed by the at least one processor, cause the QIP system at least to: determine that a first quantum circuit of the quantum circuits and a second quantum circuit of the quantum circuits are executable in tandem; combine the first quantum circuit and the second quantum circuit into a common quantum circuit for execution on the quantum hardware during a common measurement cycle; cause the quantum hardware to execute the first quantum circuit and the second quantum circuit in the common measurement cycle; and separate, upon or after termination of the common measurement cycle, a first result corresponding to execution of the first quantum circuit and a second result corresponding to execution of the second quantum circuit.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 illustrates a view of atomic ions a linear crystal or chain in accordance with aspects of this disclosure.

FIG. 2 illustrates an example of a quantum information processing (QIP) system in accordance with aspects of this disclosure.

FIG. 3 illustrates an example of a computer device in accordance with aspects of this disclosure.

FIG. 4 illustrates an example of a QIP system in accordance with aspects of this disclosure.

FIG. 5 is a schematic qubit register diagram that illustrates an example of execution of a calibration quantum circuit and a production quantum circuit in tandem, in accordance with aspects of this disclosure.

FIG. 6 is a schematic qubit register diagram that illustrates an example of a production quantum circuit that includes a single-qubit non-entangling gate, in accordance with aspects of this disclosure.

FIG. 7 is a schematic qubit register diagram that illustrates an example of execution of a calibration quantum circuit and a production quantum circuit in tandem, in accordance with aspects of this disclosure.

FIG. 8 illustrates an example of a QIP system in accordance with aspects of this disclosure.

FIG. 9 is a schematic block diagram of a computing system in accordance with one or more aspects of this disclosure.

FIGS. 10-15 illustrate examples of methods in accordance with aspects of this disclosure.

### DETAILED DESCRIPTION

The detailed description set forth below in connection with the appended drawings or figures is intended as a description of various configurations or implementations and is not intended to represent the only configurations or implementations in which the concepts described herein may be practiced. The detailed description includes specific details for the purpose of providing a thorough understanding of various concepts. However, it will be apparent to those skilled in the art that these concepts may be practiced without these specific details or with variations of these specific details. In some instances, well known components are shown in block diagram form, while some blocks may be representative of one or more well known components.

In quantum computing, a QIP system architecture having a large number of qubits is desired in order to implement computations that provide a tangible quantum advantage relative to classical computing systems. In some architectures, a large number of qubits in a trapped-atom quantum processor can be implemented in a long chain of trapped ions. A long chain of trapped ions can present a number of implementation challenges, such as structural instabilities, greater likelihood of a qubit transitioning to a dark state during computation, among other issues. Consequently, implementing a quantum computation in single, long chain of ion qubits can result in less fidelity than in a QIP system that relies on a shorter chain of qubits.

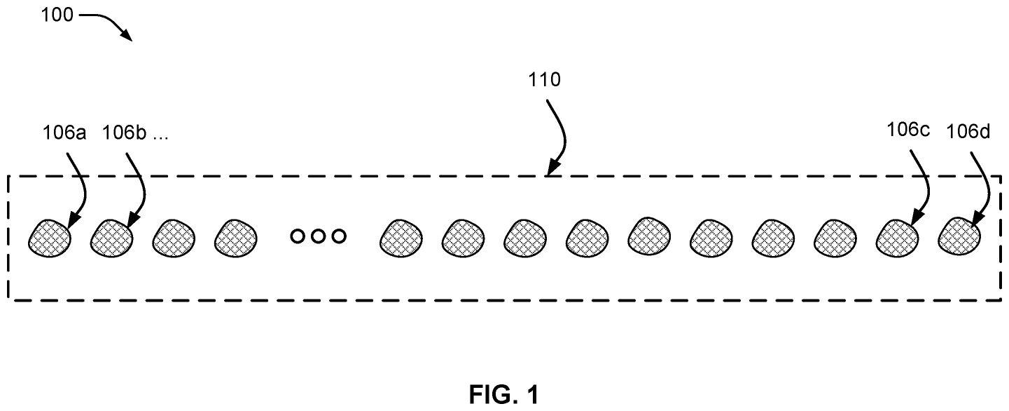

Solutions to the issues described above are explained in more detail in connection with FIGS. 1-11, with FIGS. 1-3 providing some context for QIP systems or quantum computers, and more specifically, of atomic-based QIP systems or quantum computers.

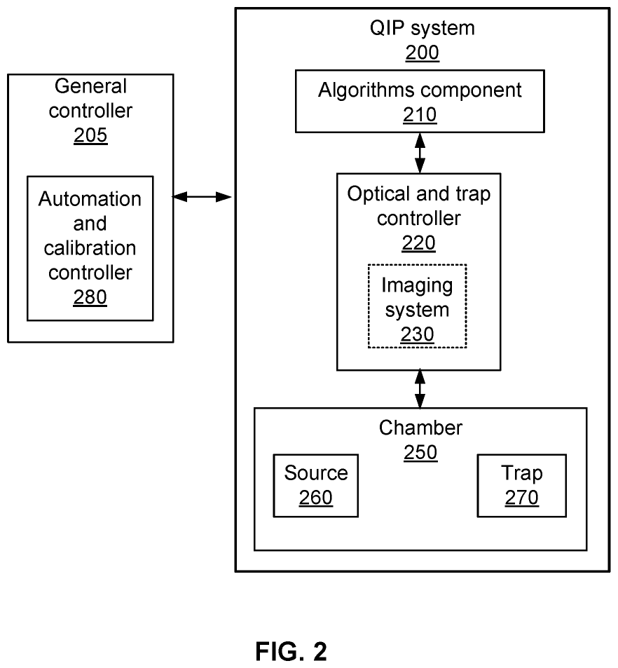

FIG. 1 illustrates a diagram 100 with multiple atomic ions or ions 106 (e.g., ions 106a, 106b, . . . , 106c, and 106d) trapped in a linear crystal or chain 110 using a trap (not shown; the trap can be inside a vacuum chamber as shown in FIG. 2). The trap maybe referred to as an ion trap. The ion trap shown may be built or fabricated on a semiconductor substrate, a dielectric substrate, or a glass die or wafer (also referred to as a glass substrate). The ions 106 may be provided to the trap as atomic species for ionization and confinement into the chain 110. Some or all of the ions 106 may be configured to operate as qubits in a QIP system.

In the example shown in FIG. 1, the trap includes electrodes for trapping or confining multiple ions into the chain 110 laser-cooled to be nearly at rest. The number of ions trapped can be configurable and more or fewer ions may be trapped. The ions can be ytterbium ions (e.g., ¹⁷¹Yb⁺ ions), for example. The ions are illuminated with laser (optical) radiation tuned to a resonance in ¹⁷¹Yb⁺ and the fluorescence of the ions is imaged onto a camera or some other type of detection device (e.g., photomultiplier tube or PMT). In this example, ions may be separated by a few microns (μm) from each other, although the separation may vary based on architectural configuration. The separation of the ions is determined by a balance between the external confinement force and Coulomb repulsion and does not need to be uniform. Moreover, in addition to ytterbium ions, barium ions, neutral atoms, Rydberg atoms, or other types of atomic-based qubit technologies may also be used. Moreover, ions of the same species, ions of different species, and/or different isotopes of ions may be used. The trap may be a linear RF Paul trap, but other types of confinement devices may also be used, including optical confinements. Thus, a confinement device may be based on different techniques and may hold ions, neutral atoms, or Rydberg atoms, for example, with an ion trap being one example of such a confinement device. The ion trap may be a surface trap, for example.

The chain 110 of ions 106 may be part of a QPU, that is, the chain 110 of ions 106 may be part of a processing engine or processing core of a QIP system. When any one of the ions 106 is capable of being connected to any other ion 106 in the chain 110, the chain 110 is considered to be fully connected, and thus, it can be used to implement a fully connected QPU. Fully connected QPUs need not be limited to atomic-based QIP systems.

FIG. 2 illustrates a block diagram that shows an example of a QIP system 200. The QIP system 200 may also be referred to as a quantum computing system, a quantum computer, a computer device, a trapped ion system, or the like. The QIP system 200 may be part of a hybrid computing system in which the QIP system 200 is used to perform quantum computations and operations and the hybrid computing system also includes a classical computer to perform classical computations and operations. The quantum and classical computations and operations may interact in such a hybrid system.

Shown in FIG. 2 is a general controller 205 configured to perform various control operations of the QIP system 200. These control operations may be performed by an operator, may be automated, or a combination of both. Instructions for at least some of the control operations may be stored in memory (not shown) in the general controller 205 and may be updated over time through a communications interface (not shown). Although the general controller 205 is shown separate from the QIP system 200, the general controller 205 may be integrated with or be part of the QIP system 200. The general controller 205 may include an automation and calibration controller 280 configured to perform various calibration, testing, and automation operations associated with the QIP system 200. These calibration, testing, and automation operations may involve, for example, all or part of an algorithms component 210, all or part of an optical and trap controller 220 and/or all or part of a chamber 250.

The QIP system 200 may include the algorithms component 210 mentioned above, which may operate with other parts of the QIP system 200 to perform or implement quantum algorithms, quantum applications, or quantum operations. The algorithms component 210 may be used to perform or implement a stack or sequence of combinations of single qubit operations and/or multi-qubit operations (e.g., two-qubit operations) as well as extended quantum computations. The algorithms component 210 may also include software tools (e.g., compilers) that, individually or in combination, permit or otherwise facilitate such performance or implementation. As such, the algorithms component 210 may provide, directly or indirectly, instructions to various components of the QIP system 200 (e.g., to the optical and trap controller 220) to enable the performance or implementation of the quantum algorithms, quantum applications, or quantum operations. The algorithms component 210 may receive information resulting from the performance or implementation of the quantum algorithms, quantum applications, or quantum operations and may process the information and/or transfer the information to another component of the QIP system 200 or to another device (e.g., an external device connected to the QIP system 200) for further processing.

The QIP system 200 may include the optical and trap controller 220 mentioned above, which controls various aspects of a trap 270 in the chamber 250, including the generation of signals to control the trap 270. The optical and trap controller 220 may also control the operation of lasers, optical systems, and optical components that are used to provide the optical beams that interact with the atoms or ions in the trap. Optical systems that include multiple components may be referred to as optical assemblies. The optical beams are used to set up the ions, to perform or implement quantum algorithms, quantum applications, or quantum operations with the ions, and to read results from the ions. Control of the operations of laser, optical systems, and optical components may include dynamically changing operational parameters and/or configurations, including controlling positioning using motorized mounts or holders. When used to confine or trap ions, the trap 270 may be referred to as an ion trap. The trap 270, however, may also be used to trap neutral atoms, Rydberg atoms, and other types of atomic-based qubits. The lasers, optical systems, and optical components can be at least partially located in the optical and trap controller 220, an imaging system 230, and/or in the chamber 250.

The QIP system 200 may include the imaging system 230. The imaging system 230 may include a high-resolution imager (e.g., CCD camera) or other type of detection device (e.g., PMT) for monitoring the ions while they are being provided to the trap 270 and/or after they have been provided to the trap 270 (e.g., to read results). In an aspect, the imaging system 230 can be implemented separate from the optical and trap controller 220, however, the use of fluorescence to detect, identify, and label ions using image processing algorithms may need to be coordinated with the optical and trap controller 220.

In addition to the components described above, the QIP system 200 can include a source 260 that provides atomic species (e.g., a plume or flux of neutral atoms) to the chamber 250 having the trap 270. When atomic ions are the basis of the quantum operations, that trap 270 confines the atomic species once ionized (e.g., photoionized). The trap 270 may be part of what may be referred to as a processor or processing portion of the QIP system 200. That is, the trap 270 may be considered at the core of the processing operations of the QIP system 200 since the trap holds the atomic-based qubits that are used to perform or implement the quantum operations or simulations. At least a portion of the source 260 may be implemented separate from the chamber 250.

It is to be understood that the various components of the QIP system 200 described in FIG. 2 are described at a high-level for case of understanding. Such components may include one or more sub-components, the details of which may be provided below as needed to better understand certain aspects of this disclosure.

Aspects of this disclosure may be implemented at least partially using one or more of the general controller 205, the automation and calibration controller 280, the optical and trap controller 220, and the chamber 250.

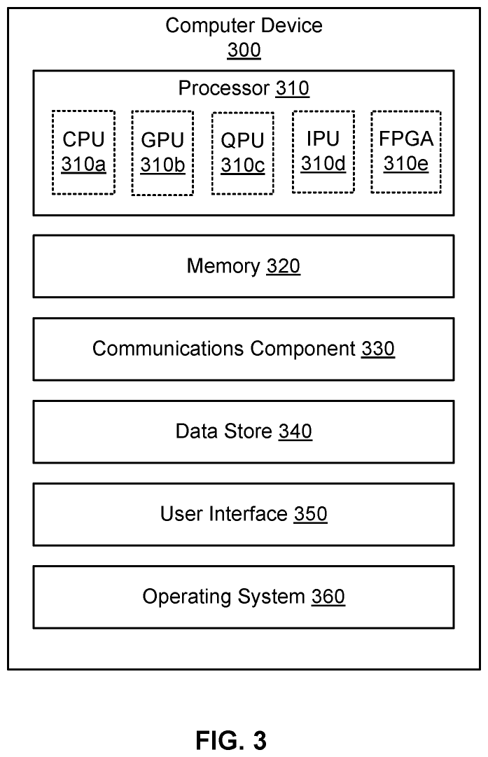

FIG. 3 illustrates an example of a computer system or computer device 300 is shown. The computer device 300 may represent a single computing device, multiple computing devices, or a distributed computing system, for example. The computer device 300 may be configured as a quantum computer (e.g., a QIP system), a classical computer, or to perform a combination of quantum and classical computing functions, sometimes referred to as hybrid functions or operations. For example, the computer device 300 may be used to process information using quantum algorithms, classical computer data processing operations, or a combination of both. In some instances, results from one set of operations (e.g., quantum algorithms) are shared with another set of operations (e.g., classical computer data processing). A generic example of the computer device 300 implemented as a QIP system capable of performing quantum computations and simulations is, for example, the QIP system 200 shown in FIG. 2.

The computer device 300 may include a processor 310 for carrying out processing functions associated with one or more of the features described herein. The processor 310 may include a single processor, multiple set of processors, or one or more multi-core processors. Moreover, the processor 310 may be implemented as an integrated processing system and/or a distributed processing system. The processor 310 may include one or more central processing units (CPUs) 310a, one or more graphics processing units (GPUs) 310b, one or more quantum processing units (QPUs) 310c, one or more intelligence processing units (IPUs) 310d (e.g., artificial intelligence or AI processors), one or more field-programmable gate arrays (FPGAs) 310e. or a combination of some or all those types of processors. In one aspect, the processor 310 may refer to a general processor of the computer device 300, which may also include additional processors 310 to perform more specific functions (e.g., including functions to control the operation of the computer device 300). Quantum operations may be performed by the QPUs 310c. Some or all of the QPUs 310c may use atomic-based qubits, however, it is possible that different QPUs are based on different qubit technologies. One or more of the QPUs 310c may be fully connected QPUs in accordance with aspects of this disclosure.

The computer device 300 may include a memory 320 for storing instructions executable by the processor 310 to carry out operations. The memory 320 may also store data for processing by the processor 310 and/or data resulting from processing by the processor 310. In an implementation, for example, the memory 320 may correspond to a computer-readable storage medium that stores code or instructions to perform one or more functions or operations. Just like the processor 310, the memory 320 may refer to a general memory of the computer device 300, which may also include additional memories 320 to store instructions and/or data for more specific functions.

It is to be understood that the processor 310 and the memory 320 may be used in connection with different operations including computations, calculations, simulations, controls, calibrations, system management, and other operations of the computer device 300, including any methods or processes described herein.

Further, the computer device 300 may include a communications component 330 that provides for establishing and maintaining communications with one or more parties utilizing hardware, software, and services. The communications component 330 may also be used to carry communications between components on the computer device 300, as well as between the computer device 300 and external devices, such as devices located across a communications network and/or devices serially or locally connected to computer device 300. For example, the communications component 330 may include one or more buses, and may further include transmit chain components and receive chain components associated with a transmitter and receiver, respectively, operable for interfacing with external devices. The communications component 330 may be used to receive updated information for the operation or functionality of the computer device 300.

Additionally, the computer device 300 may include a data store 340, which can be any suitable combination of hardware and/or software, which provides for mass storage of information, databases, and programs employed in connection with the operation of the computer device 300 and/or any methods or processes described herein. For example, the data store 340 may be a data repository for operating system 360 (e.g., classical OS, or quantum OS, or both). In one implementation, the data store 340 may include the memory 320. In an implementation, the processor 310 may execute the operating system 360 and/or applications or programs, and the memory 320 or the data store 340 may store them.

The computer device 300 may also include a user interface component 350 configured to receive inputs from a user of the computer device 300 and further configured to generate outputs for presentation to the user or to provide to a different system (directly or indirectly). The user interface component 350 may include one or more input devices, including but not limited to a keyboard, a number pad, a mouse, a touch-sensitive display, a digitizer, a navigation key, a function key, a microphone, a voice recognition component, any other mechanism capable of receiving an input from a user, or any combination thereof. Further, the user interface component 350 may include one or more output devices, including but not limited to a display, a speaker, a haptic feedback mechanism, a printer, any other mechanism capable of presenting an output to a user, or any combination thereof. In an implementation, the user interface component 350 may transmit and/or receive messages corresponding to the operation of the operating system 360. When the computer device 300 is implemented as part of a cloud-based infrastructure solution, the user interface component 350 may be used to allow a user of the cloud-based infrastructure solution to remotely interact with the computer device 300.

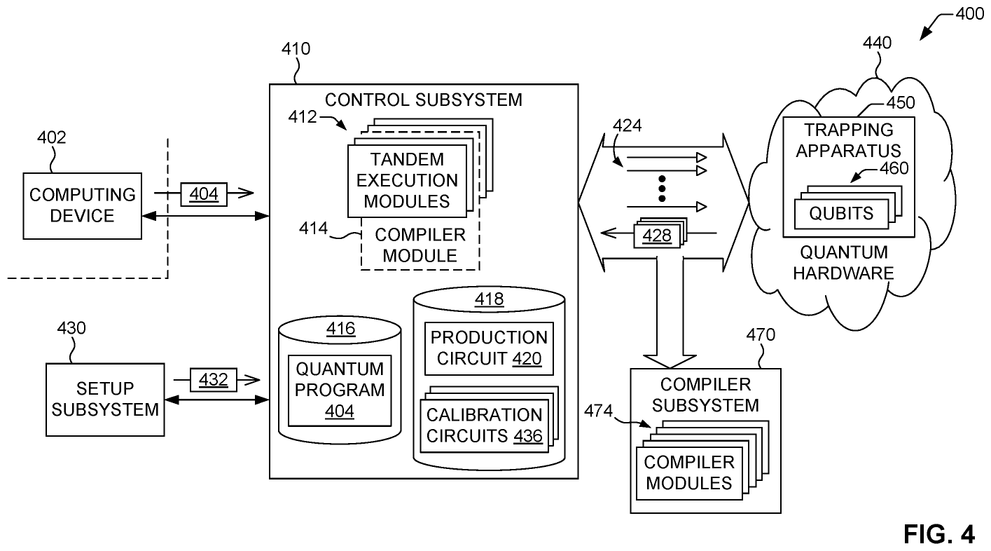

In connection with the trapped-atom systems described in FIGS. 1-3, various aspects of the technologies disclosed herein can be implemented in the example QIP system 400 illustrated in FIG. 4. Embodiments of the example QIP system 400 and other embodiments of the technologies disclosed herein address, among other technical challenges, the issue of calibration in QIP systems (or quantum computers). Calibration of a quantum computer is achieved via calibration tasks that involve execution of calibration quantum circuits in the quantum computer. Overhead associated with calibration tasks greatly reduces the production time (or uptime) of the quantum computer. Additionally, a calibration task is commonly performed in a context that is different from the context in which a production task is performed. Thus, values of parameters extracted during calibration may be systematically offset from the correct values of those parameters during execution of a circuit included in a production task. Parameters that exhibit such a systematic offset are referred to as context dependent parameters. In this disclosure, context dependency refers to a change in the actual operation of the quantum computer that depends on execution history of that quantum computer. In other words, context dependency refers to a change in current operation of the quantum computer that is dictated by operations previously executed in the quantum computer. Simply as an illustration, in trapped-atom quantum computers, thermal effects in acousto-optic modulators (AOMs) used to generate laser beams that drive quantum gates can couple laser beam alignment to the temperature of AOM crystals. Specifically, the duty cycle of a quantum computation experiment-namely, the amount of time spent performing different operations per unit time-changes the amount of radiofrequency (RF) power that is delivered to an AOM and, thus, changes the temperature of AOM crystal. In turn, such a change in temperature affects laser beam alignment, and, consequently, the calibration values required for high fidelity quantum gates.

Embodiments of the technologies described herein, individually or in combination, can simultaneously address both issues. Some embodiments include computer-implemented methods, devices, systems, computer-program products to dynamically insert calibration tasks in tandem with computation tasks. A computation task involved a computation that is configured and, in some cases executed, for purposes other than calibration. As is used in this disclosure, “tandem” refers to logically distinct subsets of a circuit (or subcircuits) executed during a common measurement cycle (also referred to as a “shot”). Based on the application associated with a computation task, these subsets can include gates that are interleaved, or executed sequentially or in parallel.

Because a single measurement cycle is involved during execution of the subsets, a single instance of state preparation, circuit execution, and measurement are involved in tandem execution. Thus, the overhead involved in state preparation and measurement can be greatly reduced relative to the approaches commonly used in existing technologies. In those existing approaches, two sub-circuits are executed in separate measurement cycles (that is, not in tandem, as is disclosed herein), thus incurring twice the overhead associated with state preparation and measurement. Further, some approaches used in existing technologies can add other inefficiencies in situations where there is additional overhead associated with changing the circuit to be executed in the quantum computer.

As a result of execution of calibration and production tasks in tandem, embodiments of the technology described herein reduce the overhead for calibration and ensuring that calibration data is obtained in the same context in which a production quantum circuit is executed. Indeed, in sharp contrast to existing QIP technologies, tandem calibration during computational circuit execution in accordance with aspects of this disclosure can permit obtaining nearly free calibration cycles, while also mitigating, at least to some extent, context dependency.

It is noted that embodiments of the technologies described herein are not limited to permitting executing calibration tasks in tandem with productions tasks. Indeed, in some cases, embodiments of this disclosure, individually or in combination, can be used to execute multiple production tasks in tandem. Ultimately, execution of quantum circuits in tandem greatly reduces overhead and also can improve circuit throughput relative to commonplace execution approaches in existing QIP technologies.

The control subsystem 410 includes various modules or other types of components configured to operate in accordance with aspects of this disclosure. As is illustrated in FIG. 4, the control subsystem 410 can include multiple tandem execution modules 412 that, individually or in combination, permit execution of quantum circuits in tandem, in accordance with aspects described herein. Although not illustrated in FIG. 4, in some cases, the example QIP system 400 can include the general controller 205 (FIG. 2) within the control subsystem 410 and the optical and trap controller 220 (FIG. 2) within quantum hardware 440.

The control subsystem 410 can obtain a quantum program 404 corresponding to a defined quantum computation. In some cases, the quantum computation is a defined N-qubit computation. To obtain the quantum program 404, the control subsystem 410 can receive data defining the quantum program 404 from a computing device 402. Although not shown in FIG. 4, the control subsystem 410 can include an intake module that can receive the quantum program 404 from the computing device 402. The control subsystem 410 can include one or multiple memory devices 416 (collectively referred to as memory 416) that retain the quantum program 404 that has been received from the computing device 402 or has been obtained in another fashion. The quantum program 404 represents a quantum algorithm. Examples of the quantum algorithm include a variational quantum algorithm, a machine-learning algorithm, a Fourier transform algorithm, and similar algorithms.

In response to obtaining the quantum program 404, the control subsystem 410 can compile the quantum program 404. To that end, the control subsystem 410 includes a compiler module 414 in some cases. In other cases, the example QIP system 400 includes a compiler subsystem 470 functionally coupled with the control subsystem 410. The compiler subsystem 470 can compile the quantum program 404 via one or more compiler modules 474. By compiling the quantum program 404, the control subsystem 410 or the compiler subsystem 474 can generate a quantum circuit. The quantum circuit can be referred to as a production quantum circuit 420. To compile the quantum program 404 the control subsystem 410 can apply one or more graph optimization methods. As a result, the control subsystem 410 obtain an optimal or otherwise satisfactory executable program form that is defined in terms of qubits and quantum gate operations involving one or more of the qubits. Specifically, the production quantum circuit 420 is defined or cast in terms of a set of qubits {q₁, q₂, . . . , q_{Q}} that can be supported by the quantum hardware 440. Here, Q is a natural number greater than 1. For example, the number of qubits contained in {q₁, q₂, . . . q_{Q}} can be the maximum number of qubits M that can be confined by the trapping apparatus 450. Thus, the quantum computation corresponding to the compiled quantum circuit can be an M-qubit computation. In some cases, the control subsystem 410, via the compiler module 414, for example, can retain data defining the production quantum circuit 420. The data can be retained within one or more memory devices 418 (collectively referred to as memory 418). The compiler module 414 can be optional (as is represented by dashed line in FIG. 4) and, in some cases, at least one of the compiler module(s) 474 can provide the functionality of the compiler module 414 as described herein.

The control subsystem 410 also retains multiple calibration quantum circuits 436 within the memory 418. The multiple calibration quantum circuits 436 are configured for calibration tasks to calibrate equipment of the quantum hardware 440. The equipment includes acousto-optic modulators (AOMs), laser devices (pulsed and/or continuous-wave laser devices), power supplies, and similar other equipment. It is noted that the calibration tasks and the equipment are specific to the quantum computing technologies used to implement a QIP system.

To configure the multiple calibration quantum circuits 436, the example QIP system 400 includes a setup subsystem 430 that is functionally coupled to the control subsystem 410. The setup subsystem 430 can send data 432 defining the multiple calibration quantum circuits 436; namely, the data 342 includes first data defining a first one the multiple calibration quantum circuits 436, second data defining a second one of the multiple calibration quantum circuits 436, and so forth. One or more quantum circuits of the multiple calibration quantum circuits 436 includes one or several of various quantum gates. Those quantum gates can include, for example, a Pauli gate (X gate or Y gate, for example); a Hadamard gate; a rotation gate; a phase shift gate); a controlled-phase shift gate; a controlled-NOT (C_{X}) gate; a Toffoli (or controlled-controlled-NOT) gate; a swap gate; a Fredkin gate; among many other quantum gates. A phase shift gate can be implemented in control hardware by advancing the phase of all subsequent operations instead of operating physically on a qubit. Rotation gates in the context of trapped-ion architectures can involve a rotation about an axis in the x-y plane (defined by an angle ϕ), by an angle θ, and can be visualized on the Bloch sphere.

Depending on calibration scheme, one or more particular circuits of the calibration circuits 436 can be hardware pulses that are not strictly quantum gates, but can probe microscopic parameters that are involved in defining a quantum gate at the computational level. For example, in trapped-ion quantum computers, the light shift experienced from a particular beam may need to be calibrated. Such a calibration can be accomplished by shining a single beam onto an ion, and measuring the accumulation of the qubit phase for the qubit embodied by the ion. Further, as another example, steerable beams are to be kept aligned to qubits. Such alignment can be accomplished by performing a rotation of a specified angle after displacing a steerable beam by a defined amount (known a priori) to each side, and then generating an error signal from the difference between an ion response in those two situations.

The control subsystem 410 can cause the quantum hardware 440 to execute the production quantum circuit 420. The control subsystem 410 also can cause the quantum hardware 440 to execute at least one particular calibration quantum circuit of the multiple calibration quantum circuits 436 as part of a calibration task. As is described herein, the production quantum circuit 420 and the at least particular calibration quantum circuit can be executed in tandem.

Execution of the production quantum circuit 420 includes manipulation of a set of qubits in a qubit register having the M qubits. The set of qubits can be referred to as qubit manifold. As part of execution of the quantum circuit, the quantum hardware 440 is directed to perform multiple measurement cycles 424 (or “shots”) in order to accumulate statistics and obtain a result of the quantum computation defined by the quantum program 404. The control subsystem 410 can receive data 428 defining outcomes of one or more shots. The data 428 also can define one or more state variables indicative of an operational condition of the quantum hardware 440 or parts thereof.

The production quantum circuit 420 includes at least one quantum gate operation and is executable in a set of first qubits of the multiple qubits 460. The set of first qubits includes N qubits: q₁, q₂, . . . q_{N-1}, and q_{N}. Although N is presented as being greater than two, the disclosure is not limited in that respect and more or fewer than two qubits can form the set of first qubits. The multiple qubits 460 includes M qubits, where M can be greater than N in some cases. Thus, the control subsystem 410 can identify a subset of the multiple qubits 460 that excludes the set of first qubits q₁, q₂, . . . q_{N-1}, and q_{N}. To that end, in some cases, the control subsystem 410 can inspect the production quantum circuit 420 and can enumerate one or more qubits that are not involved in the quantum gate operation(s) within the production quantum circuit 420. The qubit(s) that have been enumerated form the subset of the multiple qubits 460.

The subset of the multiple qubits 460 constitutes qubit resources that are available for tandem circuit execution. Accordingly, a calibration quantum circuit can be executed in the subset of the multiple qubits 460 during the measurement cycle (or shot) in which the production quantum circuit 420 is executed. In other words, the calibration quantum circuit can be executed in tandem with the production quantum circuit 420.

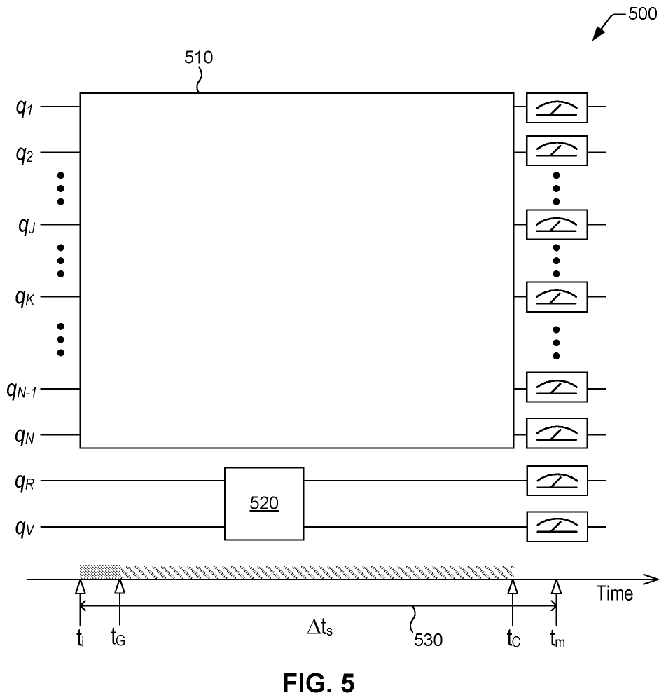

Simply as an illustration, FIG. 5 is a qubit register diagram 500 that includes a schematic representation of a production quantum circuit 510 that is executable in the N qubits in the set of first qubits {q₁, q₂, . . . q_{N-1}, and q_{N}} within a measurement cycle 530. As is illustrated, the measurement cycle 530 includes a preparation time interval that begins at a time t; and ends at a time to when the set of first qubits has relaxed to a defined many-qubit fiducial state. The preparation time interval is represented by a grey block in FIG. 5. In some cases, in trapped-ion architectures, the preparation time interval can span on the order of a few to several milliseconds, which includes time for Doppler cooling, time for sub-Doppler cooling (both of these times are to prepare the motional state of an ion chain, which impacts the gate performance), and then time for a “state preparation” phase which pumps the qubits into a desired state (the |0 [symbol] state, for example). The state preparation phase can span a few microseconds, and most of the time is spent in the Doppler/sub-Doppler cooling. In addition, the measurement cycle 530 includes a computation time interval that can begin nearly immediately after t_{G} and extends to a time t_{C}. The computation time interval is represented by a hatched block in FIG. 5. The measurement cycle 530 also includes a measurement operation at time tₘ. The entire measurement cycle 530 spans a time interval Δtₛ.

FIG. 5 also depicts a first qubit q_{R} and a second qubit qv that constitute an example subset of the multiple qubits 460 (FIG. 4). Such first and second qubits can be utilized for execution of a calibration quantum circuit 520 within the measurement cycle 530. That is, the calibration quantum circuit 520 can be executed in tandem with the production quantum circuit 510.

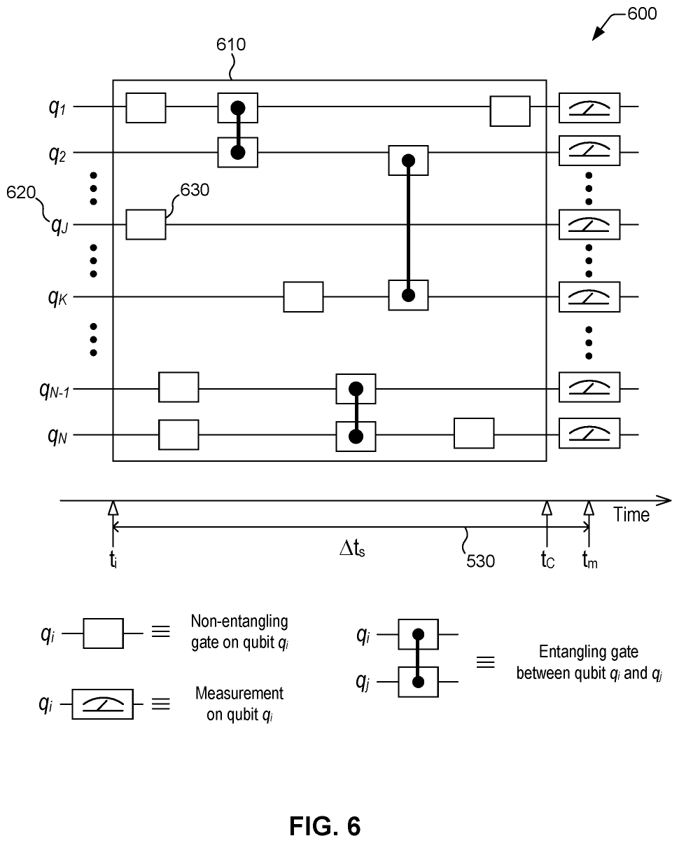

In addition, or in some cases, the control subsystem 410 can allocate, during compilation of a production quantum circuit, qubit resources for execution of a calibration quantum circuit or another production quantum circuit in tandem with the production quantum circuit. To that end, the control subsystem 410 (via the compiler module 414, for example) can identify at least one particular qubit in a qubit register that is part of one or more non-entangling gate operations included in the production quantum circuit. The control subsystem 410 can then configure the at least one particular qubit as being available for execution of a second calibration quantum circuit. In other words, the control subsystem 410 (via the compiler module 414 or another one of the multiple tandem execution modules 412) can release such particular qubit(s) from a qubit resource allocation for execution of production quantum circuit. Thus, the particular qubit(s) can be used in calibration. After release of the at least one particular qubit, the control subsystem 410 can perform one or more classical operations corresponding to one or more non-entangling gate operations associated with the at least one particular qubit. The compiler module 414 can efficiently compute such classical operation(s). The classical operation(s) can be performed independently from the execution, in the quantum hardware 440, of the remaining one or more gate operations included in the production quantum circuit. Such computation/execution of the classical operation(s) can include the application of a particular gate to a model of the ion that forms qubit a particular qubit associated with the particular gate. In one example, the particular gate is the gate 630 (FIG. 6) and the particular qubit is q_{J} (qubit 630 in FIG. 6). Stated similarly, if the structure of a quantum circuit structure is such that a subcircuit is independent and can be computed using efficient classical algorithms, such a computation is classical in nature and need not be performed on quantum hardware (e.g., quantum hardware 440 (FIG. 4)) and instead an efficient classical algorithm can be applied.

Further, in scenarios where one or more of the at least one particular qubit are not in an cigenstate of the measurement operation, the compiler module performs a classical sampling operation. For example, in a scenario the gate 630 in FIG. 6 is a GPI gate, the output state of qubit q_{J} is |1 [symbol] , as an eigenstate of the measurement operation is a state that is either a |0 [symbol] or a |1 [symbol] , but not a superposition of the two. Thus, if q_{J} is determined by a classical computation to be either |0 [symbol] or |1 [symbol] , then the output state can (ideally) always be found to be “0” or “1,” respectively. If the state of qubit q_{J} is a superposition (that is, a|0 [symbol] +b|1 [symbol] ), then the output state is found in the state “0” with probability |a|² and in the state “1” with probability |b|². The classical sampling operation includes drawing random samples from a binomial distribution with the probability of drawing a “1” equal to |b|², and injecting these samples into the returned data to reconstruct the result that would have occurred as a result of running the gate 630 using actual qubit resources.

The control subsystem 410 can then add one or more results of performing the classical operation(s) to the result of executing, in the quantum hardware 440, the remaining one or more gate operations included in the production quantum circuit. The results of performing the classical operation(s) can be added in a classical post-processing step. One or more of the tandem execution modules 412 can execution of the classical operation(s) and associated post-processing.

As an example, as is shown in FIG. 6, qubit 620 (denoted by q_{J}) is part of a non-entangling gate operation in an example production quantum circuit 610. The control subsystem 410, via the compiler module 414, for example, can configure the qubit 620 as being available for execution of a calibration quantum circuit (or, in some cases, another production quantum circuit). The control subsystem 410 (via one of multiple tandem execution modules 412, for example) can then perform a classical operation that is equivalent to the gate operation 630. The control subsystem 410 (via one of the multiple tandem execution modules 412, for example) can then add the result of performing the classical operation to the result of the quantum computation of production quantum circuit 610. The result of performing the classical operation can be added in a classical post-processing step.

In some instances, a measurement cycle corresponding to a quantum computation can stop progressing during state preparation in order to wait for one or several particular qubits present in a qubit register to be projected onto a fiducial state of the qubit register. For example, the fiducial state is the many-qubit state |00 . . . 0 [symbol] where each qubit in the qubit register is in a same single-qubit fiducial state |0 [symbol] of a two-level system |0 [symbol] and |1 [symbol] corresponding to the qubit. Each one of such particular qubit(s) can be referred to as offline qubit. Offline qubits can be present in a qubit register irrespective of quantum computing technology used to implement the qubit register. For example, offline qubits can be present in quantum computers that rely on trapped atoms (ions or neutral atoms) and quantum computers that rely on solid-state qubits. Solid-state qubits include Josephson-junction devices, semiconductor quantum dots, defects in a semiconductor material (such as vacancies in Si and Ge, or nitrogen-vacancy centers in diamond or silicon carbide), or electron spin centers in semiconductors (doped or intrinsic). Simply for purposes of illustrations, in trapped-ion architectures, this can happen if an ion “goes dark;” that is, the ion transitions to a metastable quantum state that is not part of the qubit manifold. Such a transition may happen due to a background collision, after which collision the ion relaxes to a long-lived excited state and must be pumped back to the ground state before the ion can be used as a qubit.

When an offline qubit is present in a qubit register, existing technologies typically pause the quantum computation until the qubit register is in the fiducial state. Pausing the quantum computation, however, misuses valuable qubit resources because qubits other than the particular qubit(s) can be in the appropriate single-qubit fiducial state and available to perform certain operations. In contrast to those existing technologies, rather than maintaining available qubits in an idle condition until the N-qubit fiducial state is achieved, the control subsystem 410 can allocate one or more of the available qubits in the qubit register for execution of a calibration quantum circuit (or, in some cases, a production quantum circuit). One of the multiple tandem execution modules 412 can allocate the available qubit(s) in such a fashion. The control subsystem 410, via one of the multiple tandem execution modules 412, for example, also can cause the quantum hardware 440 to execute the calibration quantum circuit during the measurement cycle. Concurrently with the execution of the calibration quantum circuit, the control subsystem 410 can control equipment within the quantum hardware 440 to cause offline qubit(s) to transition from their respective offline states to an appropriate single-qubit fiducial state; thus, ultimately causing the qubit register to transition to the many-qubit fiducial state and resuming the quantum computation. In some cases, one of the multiple tandem execution modules 412, such as an initialization module (not depicted in FIG. 4), can cause the offline qubit(s) to transition to their respective single-qubit fiducial states.

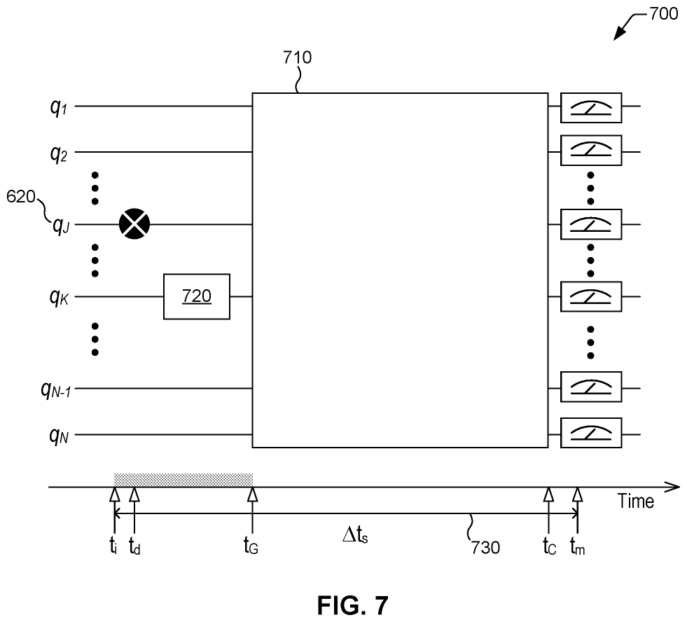

FIG. 7 is a schematic qubit register diagram 700 that illustrates an example execution of a calibration quantum circuit 720 in tandem with execution of a production quantum circuit 710, during a single measurement cycle 730. Execution of the production quantum circuit 710 begins at a time t; where each qubit in a quantum register is initialized (or prepared in fiducial state). The quantum register includes the set of qubits {q₁, q₂, . . . q_{N-1}, and q_{N}}. In a trapped-ion QIP system, state preparation includes optically pumping each qubit into an excited state of the ion that constitutes the qubit, and waiting until the ion relaxes to its ground state, which state can be the single-qubit fiducial state |0 [symbol] of the qubit. In some instances, the control subsystem 410 can determine, at a time ta, that a particular qubit 620 in the qubit register has transitioned to a dark state (or offline state). The particular qubit 620 is thus an offline qubit (represented by a black circle having a white cross overlaid thereon in FIG. 7). As mentioned, the dark state can be a long-lived excited state of the ion the embodies the qubit. In response to determining that the particular qubit 620 has transitioned to the dark state, the control subsystem 410 (via one of the multiple tandem execution modules 412, for example) can allocate other qubits (e.g., qubit q_{K}) except qubit qubit 620 for execution of the calibration quantum circuit 720. In addition, because calibration tasks typically span shorter periods of time to be completed, the control subsystem 410 (via one of the multiple tandem execution modules 412, for example) can then cause the quantum hardware 440 to execute the calibration quantum circuit 720 while the particular qubit 620 is in the dark state and/or relaxing to the one-qubit fiducial state |0 [symbol] thereof. Concurrently with the execution of the calibration quantum circuit 720, the control subsystem 410 can control or otherwise direct equipment integrated into the quantum hardware 440 to cause the particular qubit 620 to transition from the dark state to |0 [symbol] . At a time to during the measurement cycle 640, the qubit register can be initialized in the many-qubit fiducial state |00 . . . 0 [symbol] .

Prior to t_{G}, the control subsystem 410 can receive a result of the execution of the calibration quantum circuit 720. Execution of the production quantum circuit 710 can continue until a time t_{C}, after which time a measurement operation is performed at time tₘ. The control subsystem 410 can receive a result of the execution of the production quantum circuit 710 after the measurement operation is performed. In some cases, after execution of the calibration quantum circuit 720, the measurement cycle can be terminated and then started again, until qubit 620 is detected to be in the fiducial state.

The principles and practical applications of the disclosure are not limited to tandem execution of a calibration quantum circuit and a production quantum circuit. Indeed, approaches of this disclosure, individually or in combination, permit utilizing qubit resources efficiently in order to execute a first quantum circuit and a second quantum circuit in tandem, regardless of the respective types of the first and second quantum circuit. A type of the first quantum circuit is one of computation circuit or calibration circuit. Further, a type of the second quantum circuit is also one of computation circuit or a calibration circuit.

Those approaches consider a first quantum circuit and a second quantum circuit to be independent in instances where those circuits involve disjoint sets of qubits during a common measurement cycle. Such independency is a zeroth-order approximation where undesired correlations among the first and second circuit during tandem execution are disregarded. Accordingly, as is described and illustrated herein, aspects of this disclosure include the identification of disjoint sets of qubits within a quantum register that permit executing the first quantum circuit in tandem with the second quantum circuit in a common measurement cycle.

In the approaches mentioned above, the control subsystem 410 can obtain the first quantum circuit and the second quantum circuit. The first quantum circuit and the second quantum circuit can be obtained by compiling a respective quantum program or by reading from a library of quantum circuits, or both. The control subsystem 410 can obtain two types of quantum circuits in a particular combination. In some cases, the first quantum circuit is a production quantum circuit, and the second quantum circuit is a calibration quantum circuit. In other cases, the first quantum circuit is a production quantum circuit, and the second quantum circuit is another production quantum circuit. In yet other cases, the first quantum circuit is a calibration quantum circuit, and the second quantum circuit is another calibration quantum circuit.

Regardless of the types of the first and second quantum circuits, the control subsystem 410 can determine if the first quantum circuit and the second quantum circuit are executable during a common measurement cycle in the quantum hardware 440. The control subsystem 410 can perform such a determination in numerous ways. Specifically, in one example scenario, the control subsystem 410 determines that the first quantum circuit is defined in a first subset of the multiple qubits 460 present in the quantum hardware 440. As is described herein, the multiple qubits 460 can include M qubits and the first subset of the multiple qubits 460 can include N qubits, with M>N. In addition, the control subsystem 410 determines that the second quantum circuit is executable in at least one qubit in the complement of the first subset of the multiple qubits 460. The complement of the first subset includes the remaining M-N qubits.

In another example scenario, the control subsystem 410 determines that the first quantum circuit is defined in a first subset of the multiple qubits 460. In addition, the control subsystem 410 determines that at least one qubit in that first subset is part of a non-entangling gate operation. Further, the computing system determines that the second quantum circuit is executable in the at least one qubit.

Aspects of this disclosure can permit utilizing qubit resources efficiently in order to execute a first quantum circuit and a second quantum circuit in tandem, and to bound any unintended correlations arising from the tandem execution. The control subsystem 410 can determine when some types of operations are independent and, thus, can be executed in tandem.

More specifically, the control subsystem 410 can obtain a first quantum circuit and a second quantum circuit. As mentioned, the first quantum circuit and the second quantum circuit can be obtained by compiling a respective quantum program or by reading from a library of quantum circuits, or both. The control subsystem 410 can obtain two types of quantum circuits in a particular combination. A first type of quantum circuits is a production quantum circuit (or computation circuit). A second type of quantum circuits is a calibration quantum circuit (or calibration circuit). Accordingly, in some cases, the first quantum circuit is a production quantum circuit (or computation circuit), and the second quantum circuit is a calibration circuit. In addition, in other cases, the first quantum circuit is a computation circuit, and the second quantum circuit is another computation circuit. Further, in yet other cases, the first quantum circuit is a calibration circuit, and the second quantum circuit is another calibration circuit.

Regardless of the types of the quantum circuits that the control subsystem 410 has obtained, the computing system can determine if the first quantum circuit and the second quantum circuit are executable during a common measurement cycle in the quantum hardware 440 having the multiple qubits 460. The control subsystem 410 can perform such a determination in numerous ways. Specifically, in one example scenario, the control subsystem 410 determines that the first quantum circuit is defined in a first subset of the multiple qubits 460. As is described herein, the multiple qubits 460 can include M qubits and the first subset of the multiple qubits 460 can include N qubits, with M>N. In addition, the control subsystem 410 determines that the second quantum circuit is executable in at least one qubit in the complement of the first subset of the multiple qubits 460. The complement of the first subset includes M-N qubits. In another scenario, the computing system determines that the first quantum circuit is defined in a first subset of the multiple qubits. In addition, the computing system determines that at least one qubit in the first subset is part of a non-entangling gate operation. Further, the computing system determines that the second quantum circuit is executable in the at least one qubit.

In yet another scenario, the control subsystem 410 causes the quantum hardware 440 to execute the first quantum circuit, resulting in a first output state; and causes the quantum hardware to execute the second quantum circuit, resulting in a second output state. In addition, the control subsystem 410 causes the quantum hardware to execute the first quantum circuit and the second quantum circuit in a common measurement cycle, resulting in a third output state.

Imperfections in physical devices involved in configuring an ion as a qubit and addressing the qubit can cause qubits in a quantum register to interact. Such interactions can be referred to crosstalk effects and can produce undesired correlations when executing quantum circuits in tandem. In the presence of undesired correlations, quantum circuits that are executable in disjoint sets of qubits no longer can be deemed to be independent. Accordingly, to determine if a first quantum circuit and a second quantum circuit include quantum gate operations that are executable in a common measurement cycle in the presence of correlations, approaches of this disclosure include executing a series of hypothesis testing computations to determine if the output states of those computations are equivalent.

As part of such a series of hypothesis, the control subsystem 410 causes the quantum hardware 440 to execute the first quantum circuit individually. Execution of the first quantum circuit results in a first output state. In addition, also as part of the series, the control subsystem 410 causes the quantum hardware 440 to execute the second quantum circuit individually. Execution of the second quantum circuit results in a second output state. Further, still as part of the series, the control subsystem 410 causes the quantum hardware 440 to execute the first and second quantum circuits in tandem, using a first set of qubits for execution of the first quantum circuit and a second set of qubits for execution of the second quantum circuit. Execution of the first and second circuit in tandem results in a third output state. Furthermore, again as part of the series, the control subsystem 410 causes the quantum hardware 440 to execute the first and second quantum circuits in tandem, using the second set of qubits for execution of the first quantum circuit and the first set of qubits for execution of the second quantum circuit. Execution of the first and second circuit in tandem results in a fourth output state. In some cases, the control subsystem 410 determines that the first output state, the second output state, the third output state, and the fourth output state are equivalent. Hence, the control subsystem 410 determines that the first quantum circuit and the second quantum circuit include operations that are independent and, thus, arc executable in tandem in a common measurement cycle.

In example scenarios, a temporal ordering of the quantum circuits involved in tandem execution is such that a first circuit A is executed always on a first set of qubits, and a second circuit B is executed always on a second set of circuits. In some situations (ideal or otherwise), it is inconsequential if the first circuit A is first and the second circuit B is after the first circuit A, or if the second circuit B is first and then the first circuit A is after the second circuit B (or if gates are interleaved so that the first circuit A and the second circuit B are performed concurrently). However, in a scenario in which the null hypothesis that these produce identical outcomes is rejected, it is determined that there are unaccounted interactions between the first circuit A and the second circuit B, and such circuits cannot be treated independently when executed in tandem. Similar hypothesis testing computations can be performed across a reasonable sampling of circuit instances, and heuristics can be developed to determine when two circuits do not impact each other.

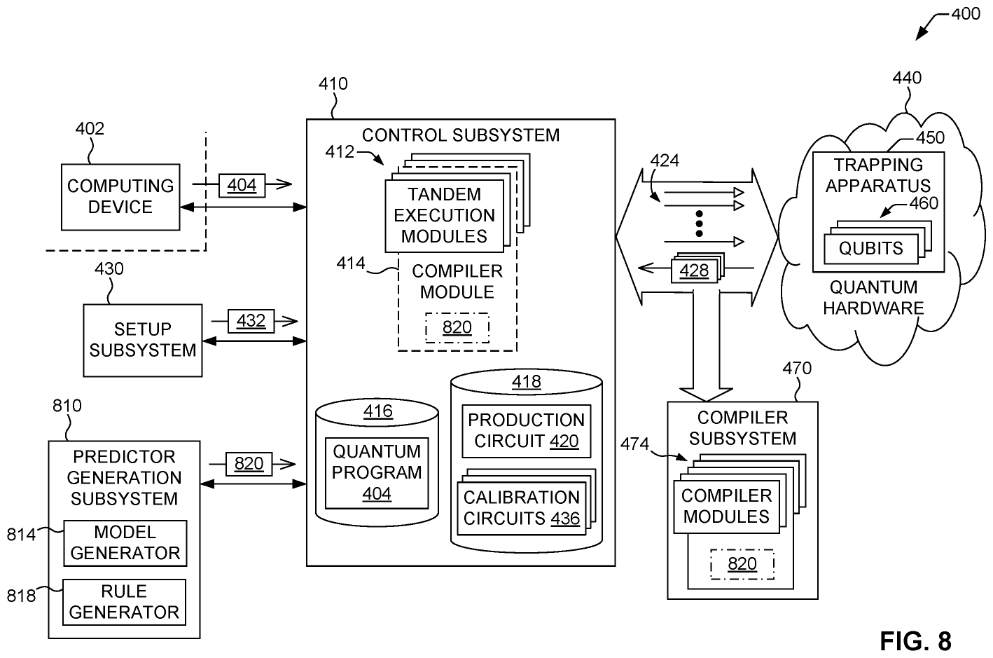

In some implementations, the predictor generation subsystem 810 (FIG. 8) can generate training data using multiple quantum circuits that include representative quantum circuits. The representative quantum circuits can include random quantum circuits and/or or quantum circuits corresponding to one or more classes of algorithms of interest (e.g., commonplace quantum computing algorithms, algorithms from quantum machine learning, quantum simulation, quantum chemistry, etc.). The multiple quantum circuits can be referred to as a bag of representative circuits. Each one of the multiple quantum circuits can be compiled (via the compiler module 414, for example) to execute in tandem on subsets of qubits of a quantum register supported by the quantum hardware 440. The predictor generation subsystem 810 can include a model generator module 814 that can draw two random circuits-first circuit A and second circuit B—from the bag of representative circuits. The model generator module 814 can then cause the quantum hardware 440 to execute the first circuit A and the second circuit B in a particular order (e.g., execute first circuit A then execute a second circuit B). Execution in that order yields a first result. The model generator module 814 can then cause the quantum hardware 440 to execute the first circuit A and the second circuit B in the opposite order to the particular order (e.g., the second circuit B then the first circuit A). Execution in such a reverse order yields a second result. The model generator module 814 can compare the first result to the second result.

The model generator module 818 can tag each of these runs according to whether the null hypothesis is rejected (that is, according to whether the answer to the question “is executing first circuit A then second circuit B different from executing circuit B then circuit A?” is affirmative or negative). Tagging a run in such a fashion can include generating a labeled pair of quantum circuits, wherein the labeled pair of quantum circuits has the first circuit A and the second circuit B and also has a classification attribute that designates the pair formed by the first circuit A and the second circuit B as belonging to a first category representative of tandem executable circuits or a second category representative of non-tandem executable circuit. After this dataset (the training set) has been generated, the quantum circuits or characteristics of the quantum circuits can be provided along with the classification attribute (e.g., a tag or another datum) for whether they exhibit correlation, into a machine learning classification algorithm. As a result, the model generator module 814 can train a machine learning model to identify whether two arbitrary circuits (not from the training dataset) are likely to exhibit crosstalk behavior, and thus cannot be executed in tandem. The model generator module 814 can send the trained machine learning model, represented by block 820 in FIG. 8, to the control subsystem 410 or the compiler subsystem 470, or both.

In addition, or an alternative, other techniques can be implemented. For example, rules can be developed, with the end result being a function ‘F (circuit A, circuit B)→bool’ returning TRUE when quantum circuit A and quantum circuit B can be executed in tandem or retuning FALSE otherwise. An example of the rules is “tandem circuits with more than N 2Q gates operated close to a particular motional mode are likely to exhibit crosstalk behavior.” The model generator module 814 can include a rule generator module 818 that can generate one or more rules that dictate whether a pair of quantum circuits can be executed in tandem. The rule generator module 818 can send the rule(s), also represented by block 820 in FIG. 8, to the control subsystem 410 or the compiler subsystem 470, or both.

In addition, or in some cases, microscopic crosstalk channels can be determined via standard characterization techniques, and the impact of executing circuits in tandem calculated directly in simulation. The predictor generation subsystem 810 (FIG. 8) can perform a simulation in order to evaluate the impact of running circuits in tandem. To that end, a monitor subsystem (not depicted in FIG. 8) can generate data The predictor generation subsystem 810 can receive such data from the monitor subsystem. In some cases, as an illustration, a gate between qubit 1 and qubit 2 can be characterized, including crosstalk to neighboring qubit 0 and qubit 3. Then, two quantum circuits can be proposed to run in tandem, the first circuit using qubits [1, 2] and the second circuit using qubits [0, 3]. If the first quantum circuit is executed, the result using the full qubit subspace [0,1,2,3] is simulated, and it can be determined that the initial state when quantum circuit 2 is implemented will be different from the (presumed) fiducial state |00 [symbol] due to microscopic crosstalk channels characterized with the gate between qubit 1 and qubit 2. Such an approach can be implemented in smaller circuit instances in order to avoid using a large amount of resources required to perform the simulation, which amount can scale exponentially in the number of qubits. Other machine-learning approaches described herein can be more applicable to larger circuit instances.

An example of a microscopic crosstalk channel is Rabi crosstalk to a neighboring qubit—if a gate is applied on qubit q₁, then neighboring qubits q₀ and q₂ experience that gate with a fraction of the strength seen by qubit q₁. In simulation, this model can be used to predict an outcome of two quantum circuits, and determine if the results satisfy a null hypothesis. Another example of microscopic crosstalk channel is phase-space nonclosure on an MS gate: applying an MS gate on qubits (0, 1) that uses motional mode A may leave some residual entanglement on mode A. At a later time, an MS gate applied on qubits (4, 8) that also uses motional mode A can start from a different initial condition than if the first gate on (0, 1) had not been applied. This can also be simulated, and the null hypothesis tested.

In some cases, the control subsystem 410 or another computing system that includes the tandem execution modules 412 can inspect quantum circuits, determine if the quantum circuits are able to execute in tandem, combine the quantum circuits into a single quantum circuit for execution on the quantum hardware 440 during a single measurement cycle, and then separate the results at the end of the measurement cycle as if the quantum circuits were executed separately. Combining a first quantum circuit and a second quantum circuit for tandem execution can include configuring the first quantum circuit to execute in a first subset of qubits in a qubit register and configuring the second quantum circuit in the second subset of qubits in the qubit register. The second subset is the complement of the first subset. In other words, combining the first quantum circuit and the second quantum circuit effectively overlays the first quantum circuit and the second quantum circuit across sub-registers of qubits.

In some cases, the results can be separated by a particular process that can be executed by one or more of the tandem execution modules 412. Such a particular process (which can be referred to as a separation process) can inspect the entire result from both the first subset of qubits and the second subset of qubits, and can trace out the second set of qubits to generate a result for the quantum circuit executed on the first subset of qubits. Similarly, the particular process can trace out the first subset of qubits to generate a result for the quantum circuit executed on the second set of qubits. The particular process can thus generate multiple distinct sets of results, one for each circuit that was executed in tandem, based on the combined result across all qubits that is returned from the quantum hardware 440. These distinct sets of results can then be processed separately in the control subsystem 410 or other subsystems (not depicted in FIG. 4) as though the circuits were executed independently of each other.

To trace out a subset of qubits within a qubit register and generate a result for execution of a quantum circuit on the subset of qubit, the particular process can obtain a bitstring representing a result of execution of a quantum circuit and another quantum circuit on both the subset of qubits and another subset of qubits. A particular module (e.g., a schedule module) of the tandem execution modules 412 can allocate the subset of qubits for execution of the quantum circuit and the other subset of qubits to the other quantum circuit. A second particular module of the tandem execution modules 412, in response to implementing the separation process, can identify values of bits in the bitstring that are associated with measurements in each qubit in the subject of qubits. The second particular module can then generate a shorter bitstring where each bit has a value that is equal to a respective one of the identified values of bits in the bitstring. The shorter bitstring represents the traced-out result for the quantum circuit. Further in response to implementing the separation process, the second particular module can identify second values of bits in the bitstring that are associated with measurements in each qubit in the other subset of qubits. The second particular module can then generate a second shorter bitstring where each bit has a value that is equal to a respective one of the identified second values of bits in the bitstring. The second shorter bitstring represents the traced-out result for the other quantum circuit.

Simply as an illustration, in an example scenario where four qubits {q₁, q₂, q₃, q₄} are available for computation, a scheduler module of the tandem execution modules 412 can allocate qubit q₁ and qubit q₂ to a quantum circuit A, and can further allocate qubit q₃ and qubit q₄ to a quantum circuit B. A result of execution of quantum circuit A and quantum circuit B during a common measurement cycle is a bitstring on the entire set {q₁, q₂, q₃, q₄}. In one example, the bitstring may be “0011,” indicating qubits q₁ and q₂ are measured to be in state |0 [symbol] , and qubits q₃ and q₄ are measured to be in a state |1 [symbol] . In such example scenario, implementation of the separation process described herein to trace out qubits q₃ and q₄ yields the shorter bitstring “00.” Similarly, implementation of the separation process described herein to trace out qubits q₁ and q₂ yields the bitstring “11.”

In addition, or in other cases, one or more of the tandem execution modules 412 can optionally remap circuits over the available qubit resources, to optimally compress multiple circuits into a single tandem execution. Other optimizations can be performed to increase overall throughput, for example, combining qubit remapping symmetrization (diversification) with the needs of calibration. In addition, or in yet other cases, a single circuit using M<N qubits is remapped by the compiler module 414 in multiple shots across the full N qubits available in the quantum computer, to implement qubit remapping symmetrization. The calibration logic can thus refresh calibrations across the entire qubit register because each qubit can be available for tandem circuit execution during some portion of the symmetrized execution of a quantum algorithm.

After determining that the first and second quantum circuits are executable in a common measurement cycle, the control subsystem 410 causes the quantum hardware 440 to execute the first quantum circuit and the second quantum circuit in the common measurement cycle, resulting in an output state.

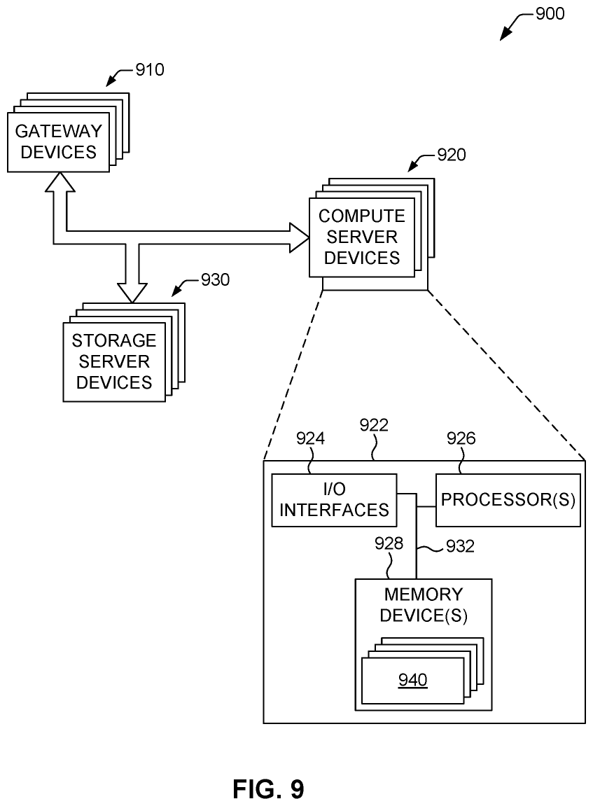

FIG. 9 is a schematic block diagram of an example of a computing system 900, in accordance with one or more embodiments of this disclosure. The example computing system 900 can embody, or can be part of, the control subsystem 410, the setup subsystem 430, the compiler subsystem 470, the predictor generation subsystem 810, or a combination of those subsystems, described herein in connection with example systems of this disclosure. Accordingly, the example computing system 900 can provide at least some of the functionality described herein in connection with tandem execution of quantum circuits in accordance with aspects described herein.

The computing system 900 includes multiple computing devices that can be arranged in a cloud architecture. As such, the example computing system 900 includes two types of server devices: Compute server devices 920 and storage server devices 930. A subset of the compute server devices 920, individually or collectively, can host various modules 940 that permit implementing execution of quantum circuits in tandem in accordance with aspects described herein. Thus, the subset of compute server devices 920 can operate in accordance with functionality described herein in connection with one of the control subsystem 410, the setup subsystem 430, the compiler subsystem 470, or the predictor generation subsystem 810, or a combination of those subsystems. The architecture of each of the compute server devices 920—as is illustrated with reference to a particular compute server device 1122—includes multiple input/output (I/O) interfaces 924, one or more processors 926, one or more memory devices 928, and a bus architecture 932 that functionally couples the processor(s) 924, the memory device(s) 928, and the I/O interfaces 924. In some cases, the compute server device 922 can store the modules 940 in at least one of the memory device(s) 928. The compute server device 922 also can store other modules in the memory device(s) 928, where those other modules provide some functionality of the compute server device 922.

At least the subset of the compute server devices 920 can be functionally coupled to one or multiple ones of the storage server devices 930. The coupling can be direct or can be mediated by at least one of the gateway devices 910. The storage server devices 930 include data and/or metadata that can be used to implement the functionality described herein in connection with tandem execution of quantum circuits in accordance with aspects described herein.

Each one of the gateway devices 910 can include one or multiple processors functionally coupled to one or multiple memory devices that can retain application programming interfaces (APIs) and/or other types of program code for accessing to the compute server devices 920 and storage server devices 930. Such access can be programmatic, via a defined function call, for example. The subset of the compute server devices 920 that host one or a combination of modules (e.g., modules 940) that can use API(s) supplied by the gateway devices 910 in order to provide results of implementing the functionalities described herein in connection with tandem execution of quantum circuits in accordance with aspects described herein.

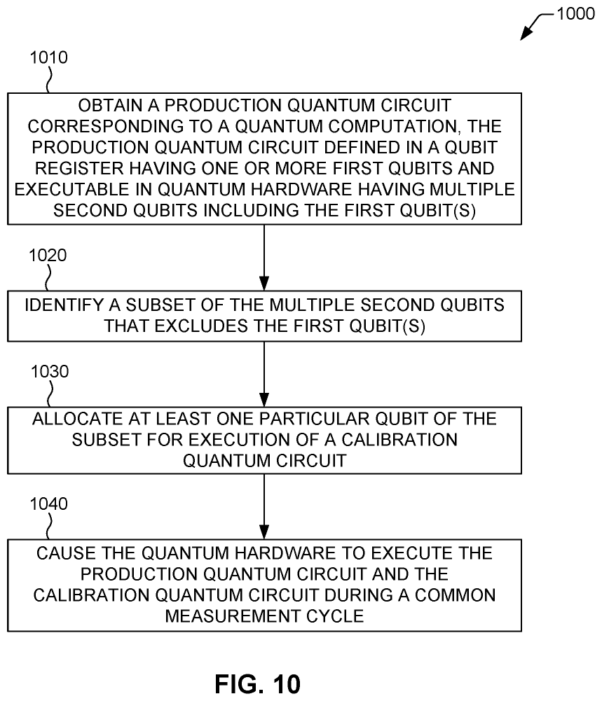

Example of methods that can be implemented in accordance with this disclosure can be better appreciated with reference to FIGS. 10-15. For purposes of simplicity of explanation, example methods disclosed herein are presented and described as a series of acts. The example methods are not limited by the order of the acts, as some acts may occur in different orders and/or concurrently with other acts from that shown and described herein. In some cases, one or more example methods disclosed herein can alternatively be represented as a series of interrelated states or events, such as in a state diagram depicting a state machine. In addition, or in other cases, interaction diagram(s) (or process flow(s)) may represent methods in accordance with aspects of this disclosure when different entities enact different portions of the methodologies. It is noted that not all illustrated acts may be required to implement a described example method in accordance with this disclosure. It is also noted that two or more of the disclosed example methods can be implemented in combination with each other, to accomplish one or more functionalities described herein.

Methods disclosed herein can be stored on an article of manufacture in order to permit or otherwise facilitate transporting and transferring such methodologies to computers or other types of information processing apparatuses for execution, and thus implementation, by one or more processors, individually or in combination, or for storage in a memory device or another type of non-transitory computer-readable storage device. In one example, one or more processors that enact a method or combination of methods described herein can be utilized to execute program code retained in a memory device, or any processor-readable or machine-readable storage device or non-transitory media, in order to implement method(s) described herein. The program code, when configured in processor-executable form and executed by the one or more processors, causes the implementation or performance of the various acts in the method(s) described herein. The program code thus provides a processor-executable or machine-executable framework to enact the method(s) described herein. Accordingly, in some cases, each block of the flowchart illustrations and/or combinations of blocks in the flowchart illustrations can be implemented in response to execution of the program code.

FIG. 10 is a flowchart of an example method 1000 for executing quantum circuits in tandem within quantum hardware, in accordance with one or more aspects of this disclosure. A computing device or a system of computing devices can implement the example method 1000 in its entirety or in part. To that end, each one of the computing devices includes computing resources that may implement at least one of the blocks included in the example method 1000 and other methods described herein. The computing resources comprise, for example, central processing units (CPUs), graphics processing units (GPUs), tensor processing units (TPUs), field-programmable gate arrays (FPGAs), memory, disk space, incoming bandwidth, and/or outgoing bandwidth, interface(s) (such as I/O interfaces or APIs, or both); controller devices(s); power supplies; a combination of the foregoing; and/or similar resources. In some cases, a computing system implements the example method 1000. The computing system can host at least the tandem execution modules 412 (FIG. 4) and can implement the example method 1000 by executing one or more instances of such modules. The control subsystem 410 (FIG. 4) can embody or can constitute such a computing system.

At block 1010, the computing system can obtain a production quantum circuit corresponding to a quantum computation. As mentioned, the quantum computation can be a defined N-qubit computation. The production quantum circuit is defined in a qubit register having one or more first qubits. The production quantum circuitry is executable the quantum hardware (e.g., quantum hardware 440) having multiple second qubits including the one or more first qubits. Obtaining the production quantum circuit can include compiling a quantum program.

At block 1020, the computing system can identify a subset of the multiple second qubits that excludes the one or more first qubits.

At block 1030, the computing system can allocate at least one particular qubit of the subset for execution of a calibration quantum circuit. The computing system can obtain the calibration quantum circuit by reading data defining the calibration circuit from a library or queue of defined calibration circuits.

At block 1040, the computing system can cause the quantum hardware to execute the production quantum circuit and the calibration quantum circuit during a common measurement cycle.

Although not illustrated in FIG. 10, in some embodiment, the example method 900 also can include determining that at least one particular qubit of the one or more first qubits is part of a non-entangling gate operation. In response to such a determination, the example method 900 includes configuring the at least one particular qubit as being available for execution of a second calibration quantum circuit. In other words, the computing system can release such particular qubit(s) for use in calibration. In scenarios involving such a release of the at least one particular qubits, the execution of the production quantum circuit during the measurement cycle includes performing one or more classical operations corresponding to one or more quantum mechanical operations associated with the at least one particular qubit. In addition, or in some cases, the example method 1000 also can include adding a result of performing the one or more classical operations to a second result of performing one or more second quantum mechanical operations corresponding to the production quantum circuit.

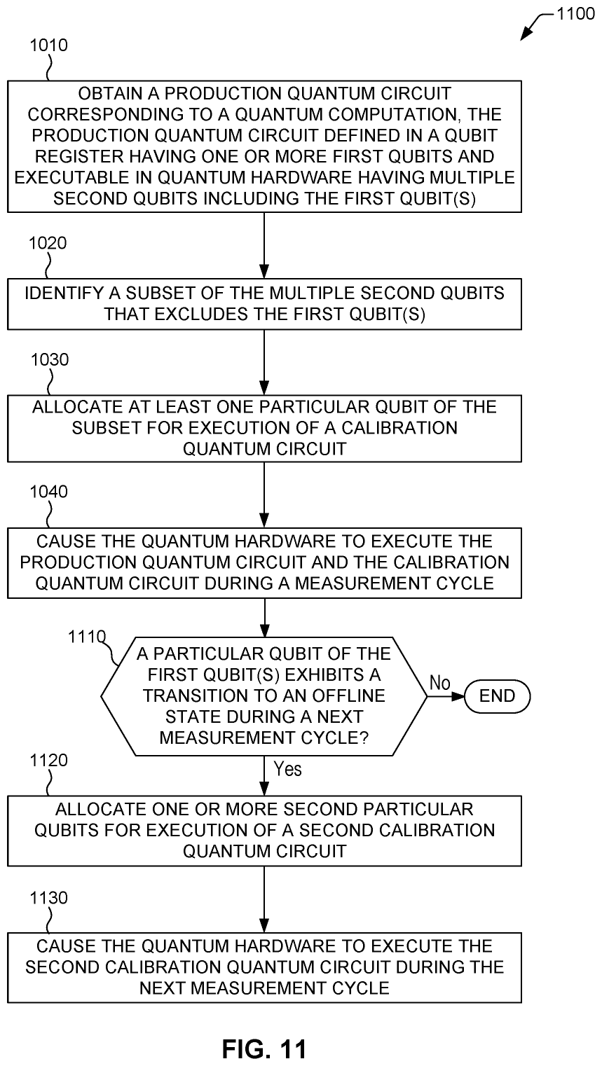

As is illustrated in FIG. 11, the example method 1000 (FIG. 10) can be combined with other operations in order to use available resources for efficiently implementing calibration. FIG. 11 is a flowchart of an example method 1100 for executing quantum circuits in tandem, in accordance with one or more aspects of this disclosure. The computing system that implements the example method 1000 also can implement the example method 1100 in its entirety or in part.

The example method 1100 includes blocks 1010-1040. The computing system can implement such blocks, individually or in combination, in accordance with aspects described hereinbefore in connection the example method 1000 (FIG. 10).

At block 1110, the computing system can determine, during a second measurement cycle, if a particular qubit of the one or more first qubits has transitioned to an offline state. Such a particular qubit can be referred to as dark qubit or dark ion. A negative determination (“No” branch) results in the flow of the example method 1100 being terminated. An affirmative determination (“Yes” branch) results in the flow of the example method continuing to block 1120, where the computing system can allocate one or more second particular qubits for execution of a second calibration quantum circuit. The one or more second particular qubits pertain to a set of qubits that includes the multiple second qubits less the dark qubit. Further, as part of the “Yes” branch, at block 1130, the computing system can cause the quantum hardware to execute the second calibration quantum circuit during the next measurement cycle.

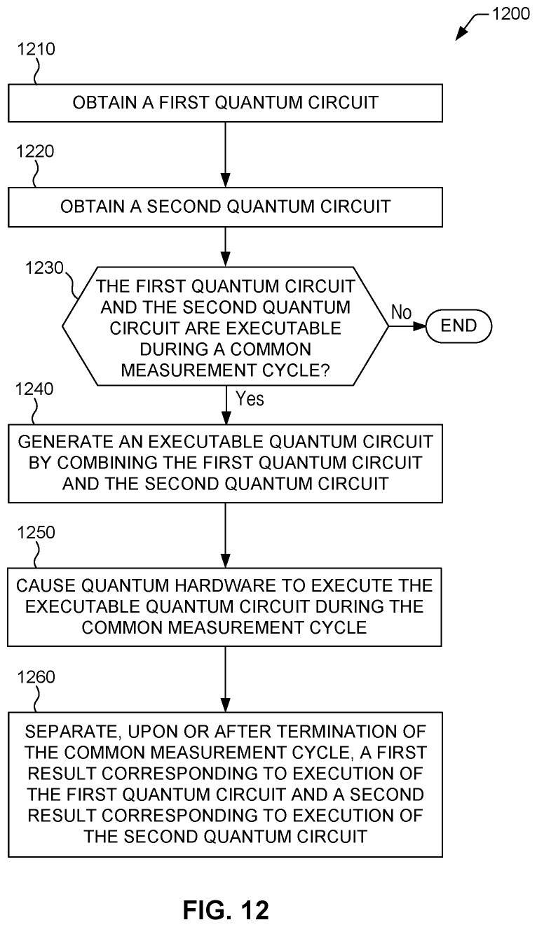

FIG. 12 is a flowchart of an example method 1200 for executing two quantum circuits in tandem, in accordance with one or more aspects of this disclosure. A computing device or a system of computing devices can implement the example method 1200 in its entirety or in part. To that end, each one of the computing devices includes computing resources that may implement at least one of the blocks included in the example method 1200 and other methods described herein. The computing resources comprise, for example, CPUs, GPUs, TPUs, FPGAs, memory, disk space, incoming bandwidth, and/or outgoing bandwidth, interface(s) (such as I/O interfaces or APIs, or both); controller devices(s); power supplies; a combination of the foregoing; and/or similar resources. In some cases, a computing system implements the example method 1200. The computing system can host at least the tandem execution modules 412 (FIG. 4) and can implement the example method 1200 by executing one or more instances of such modules. The control subsystem 410 (FIG. 4) can embody or can constitute such a computing system.

At block 1210, the computing system can obtain a first quantum circuit. In some cases, obtaining the first quantum circuit includes compiling a quantum program. In other cases, obtaining the first quantum circuit includes reading data defining the first quantum circuit from a library or queue of quantum circuits.

At block 1220, the computing system can obtain a second quantum circuit. In some cases, obtaining the second quantum circuit includes compiling another quantum program. In other cases, obtaining the second quantum circuit includes reading data defining the second quantum circuit from a library or queue of quantum circuits. Such a queue can be the same queue of quantum circuits that includes the first quantum circuit.

The computing system can obtain a particular combination of types of first and second quantum circuits. In some cases, the first quantum circuit is a computation circuit, and the second quantum circuit is a calibration circuit. In other cases, the first quantum circuit is a computation circuit, and the second quantum circuit is another computation circuit. In yet other cases, the first quantum circuit is a calibration circuit, and the second quantum circuit is another calibration circuit.

Regardless of the types of the quantum circuits that have been obtained, at block 1230, the computing system can determine if the first quantum circuit and the second quantum circuit are executable during a common measurement cycle in quantum hardware having multiple qubits. The multiple qubits can constitute a quantum register. For example, the multiple qubits can be the set of qubits {q₁, q₂, . . . q_{Q-1}, and q_{Q}} that is supported by the quantum hardware. In some scenarios, the computing system can perform a negative determination. As a result (“No” branch), the example method 1200 can be terminated.

In other scenarios, the computing system can perform an affirmative determination. Specifically, in one example scenario, the computing system determines that the first quantum circuit is defined in a first subset of the multiple qubits. In addition, the computing system determines that the second quantum circuit is executable in at least one qubit in the complement of the first subset. In another example scenario, the computing system determines that the first quantum circuit is defined in a first subset of the multiple qubits. In addition, the computing system determines that at least one qubit in the first subset is part of a non-entangling gate operation. Further, the computing system determines that the second quantum circuit is executable in the at least one qubit. In yet another example scenario, the computing system causes the quantum hardware to execute the first quantum circuit, resulting in a first output state; and causes the quantum hardware to execute the second quantum circuit, resulting in a second output state. In addition, the computing system causes the quantum hardware to execute the first quantum circuit and the second quantum circuit in a common measurement cycle, resulting in a third output state. Further, the computing system causes the quantum hardware to execute the first quantum circuit and the second quantum circuit in a second common measurement cycle, resulting in a fourth output state. The computing system then determines that the first output state, the second output state, the third output state, and the fourth output state are equivalent.

An affirmative determination (“Yes” branch) results in the example method 1200 continuing to block 1240, where the computing system can generate an executable quantum circuit by combining the first quantum circuit and the second quantum circuit.

At block 1250, the computing system can cause the quantum hardware to execute the executable quantum circuit during the common measurement cycle.

At block 1260, the computing system can separate a first result corresponding to execution of the first quantum circuit and a second result corresponding to the execution of the second quantum circuit. The first result and second result can be separated upon termination of the common measurement cycle or after the common measurement has ended. Separating the first and second result can include analyzing a result from the first subset of qubits and the second subset of qubits. In addition, the separating includes generating the first result by tracing the second subset of qubits out based on an outcome of such analysis, and generating the second result by tracing the first subset of qubits out based on the outcome of such analysis.

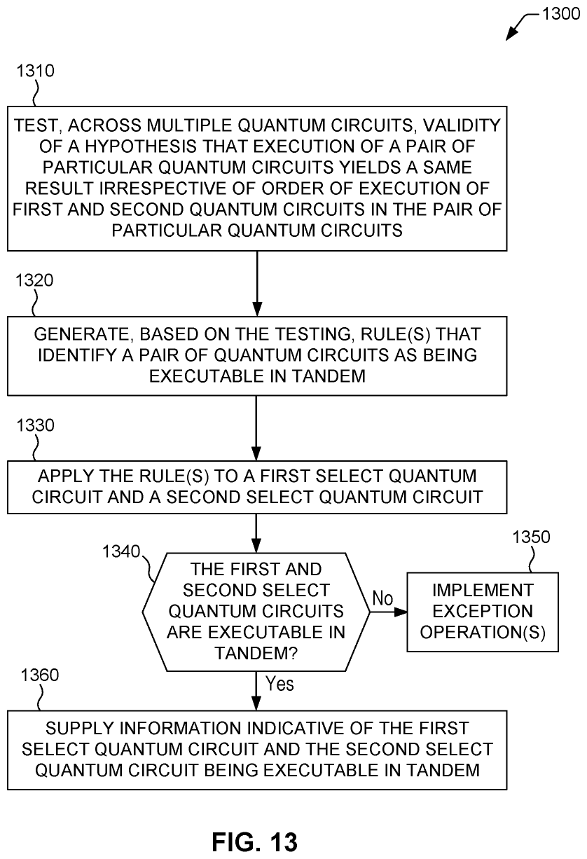

FIG. 13 is a flowchart of an example method for automatically identifying quantum circuits executable in tandem, in accordance with one or more aspects of this disclosure. A computing device or a system of computing devices can implement the example method 1300 in its entirety or in part. To that end, each one of the computing devices includes computing resources that may implement at least one of the blocks included in the example method 1300 and other methods described herein. The computing resources comprise, for example, CPUs, GPUs, TPUs, FPGAs, memory, disk space, incoming bandwidth, and/or outgoing bandwidth, interface(s) (such as I/O interfaces or APIs, or both); controller devices(s); power supplies; a combination of the foregoing; and/or similar resources.

In some cases, a computing system implements the example method 1300. The computing system can host, for example, at least the tandem execution modules 412 (FIG. 4) and the rule generator module 818 (FIG. 8), and can implement the example method 1300 by executing one or more instances of such modules. The control subsystem 410 (FIG. 4) and the predictor generation subsystem 810 (FIG. 8) can embody or can constitute such a computing system.

At block 1310, the computing system can test, across multiple quantum circuits, validity of a hypothesis that execution of a pair of particular quantum circuits yields a same result irrespective of order of execution of first and second quantum circuits in the pair of particular quantum circuits.

At block 1320, the computing system can generate, based on the testing, one or more rules, or in some cases other heuristics, to identify a pair of quantum circuits as being executable in tandem. In some cases, the computing system can generate at least one of the rule(s) by executing a software module, such as an autonomous bot that applies a generative machine-learning model. In one an example, the generative machine-learning model can be or can include a generative adversarial network (GAN). In cases where computing system generates heuristics, generating the heuristics can include generating instructions that define or otherwise configure a technique to identify the pair of quantum circuits as being executable in tandem. The instructions can include, for example, program code (executable or otherwise) and/or other software components. The technique can correspond to any of the techniques or other methods described herein. In one example, the computing system can generate heuristics by executing the above-mentioned software module or another software module, such as another autonomous bot that applies a generative machine-learning model to generate such instructions. The generative machine-learning model can be or can include a generative adversarial network (GAN).

At block 1330, the computing system can apply at least one of the rule(s) (or, in some cases, the heuristics) to a first select quantum circuit and a second select quantum circuit.

At block 1340, the computing system can determine if the first select quantum circuit and the second select quantum circuit are executable in tandem. A negative determination (“No” branch) results in the example method 1300 continuing to block 1350, where the computing system can implement one or more exception operations. Simply for purposes of illustration, an exception operation includes one or more action that, in response to being implemented, supply information indicative of the first and second select quantum circuits not being executable in tandem. In the alternative, an affirmative determination (“Yes” branch) results in the example method 1300 continuing to block 1360, where the computing system can supply information indicative of the first select quantum circuit and the second select quantum circuit being executable in tandem.

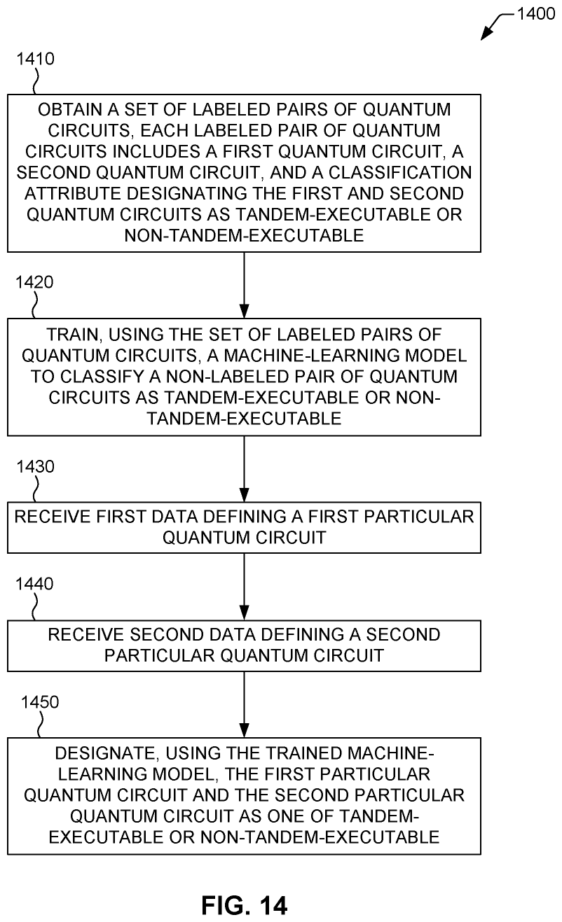

FIG. 14 is a flowchart of another example method for automatically identifying quantum circuits executable in tandem, in accordance with one or more aspects of this disclosure. A computing device or a system of computing devices can implement the example method 1300 in its entirety or in part. To that end, each one of the computing devices includes computing resources that may implement at least one of the blocks included in the example method 1300 and other methods described herein. The computing resources comprise, for example, CPUs, GPUs, TPUs, FPGAs, memory, disk space, incoming bandwidth, and/or outgoing bandwidth, interface(s) (such as I/O interfaces or APIs, or both); controller devices(s); power supplies; a combination of the foregoing; and/or similar resources.

In some cases, a computing system implements the example method 1400. The computing system can host at least the tandem execution modules 412 (FIG. 4) and the model generator module 814 (FIG. 8), and can implement the example method 1400 by executing one or more instances of such modules. The control subsystem 410 (FIG. 4) and the predictor generation subsystem 810 (FIG. 8) can embody or can constitute such a computing system. The computing system that implements the example method 1400 can be the same computing system that implements the example method 1300.

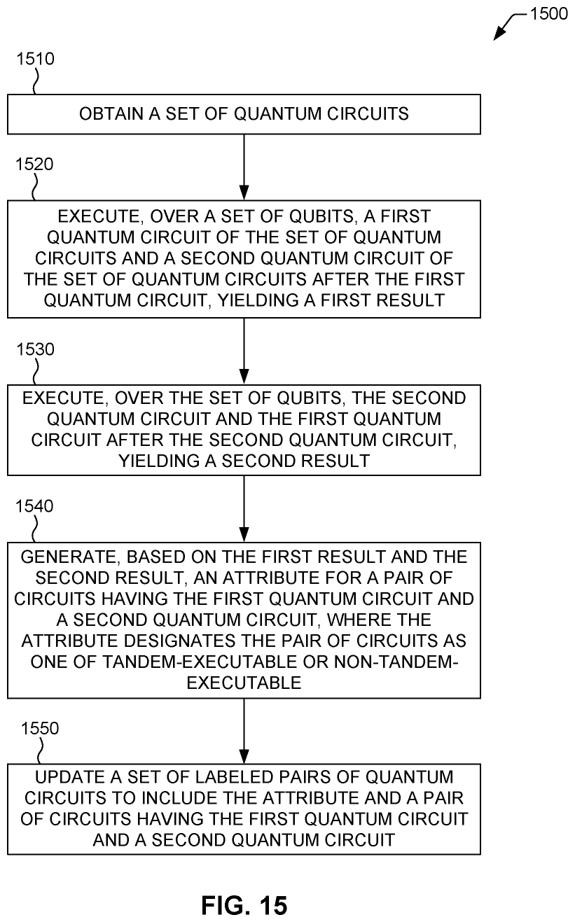

At block 1410, the computing system can obtain a set of labeled pairs of quantum circuits. A labeled pair of quantum circuits includes a first quantum circuit, a second quantum circuit, and a classification attribute designating the first quantum circuit and the second quantum circuit as one of tandem-executable or non-tandem-executable. The computing system can obtain the set of labeled pairs in numerous ways. For example, the computing system can implement the example method 1500 (FIG. 15) to obtain the set of labeled pairs of quantum circuits.

The set of labeled pairs of quantum circuits can form a dataset for training a predictive model to identify a non-labeled pair of quantum circuits as tandem-executable or non-tandem-executable. The predictive model is, in some cases, a machine-learning model that solves a binary classification task. At block 1420, the computing system can train, using the set of labeled pairs of quantum circuits, the machine-learning model to classify a non-labeled pair of quantum circuits as tandem-executable or non-tandem-executable.

At block 1430, the computing system can receive first data defining a first particular quantum circuit (e.g., a computation quantum circuit or a calibration quantum circuit). The first data can be received from a computing device that is remotely located relative to the computing system. In one example, the computing device can be, or can include, the computing device 402 (FIG. 4).

At block 1430, the computing system can receive second data defining a second particular quantum circuit (e.g., a computation quantum circuit or a calibration quantum circuit). The second data also can be received from the computing device that supplies the first data. In other cases, the second data can be received from another computing device. That other computing device can be part of the computing system or also can be remotely located relative to the computing system.

In one example scenario, the first particular quantum circuit is a computation quantum circuit, and a customer device provides the first data defining the computation quantum circuit. In addition, the second particular quantum circuit is a calibration circuit, and a computing device that is part of the computing system supplies the second data.

At block 1440, the computing system can designate, using the trained machine-learning model (e.g., predictive model 820 (FIG. 8)), the particular first quantum circuit and particular second circuit as one of tandem-executable or non-tandem-executable. To that end, the computing system can determine a particular classification attribute by applying the trained machine-learning model to the first data and the second data. The particular classification attribute designates the first particular quantum circuit and the second particular quantum circuit as one of tandem-executable or non-tandem-executable.s

FIG. 15 is a flowchart of an example method for obtaining a set of labeled pairs of quantum circuits, in accordance with one or more aspects of this disclosure. A computing device or a system of computing devices can implement the example method 1500 in its entirety or in part. To that end, each one of the computing devices includes computing resources that may implement at least one of the blocks included in the example method 1500 and other methods described herein. The computing resources comprise, for example, CPUs, GPUs, TPUs, FPGAS, memory, disk space, incoming bandwidth, and/or outgoing bandwidth, interface(s) (such as I/O interfaces or APIs, or both); controller devices(s); power supplies; a combination of the foregoing; and/or similar resources.

In some cases, a computing system implements the example method 1500. The computing system can host at least the tandem execution modules 412 (FIG. 4) and can implement the example method 1500 by executing one or more instances of such modules. The control subsystem 410 (FIG. 4) can embody or can constitute such a computing system. The computing system that implements the example method 1500 can be the same computing system that implements the example method 1400.

At block 1510, the computing system can obtain a set of quantum circuits. In some cases, the set of quantum circuits includes at least one random quantum circuit or at least one quantum circuit corresponding a defined class of algorithms, or a combination thereof. The defined class of algorithms can be one of quantum machine learning, quantum simulation, or quantum chemistry. The disclosure, however, is not limited in that respect and other classes of algorithms are contemplated.

At block 1520, the computing system can execute, over a set of qubits, a first quantum circuit of the particular circuits and a second quantum circuit of the particular quantum circuits after the first quantum circuit. Execution of the first and second quantum circuits in that order yields a first result. The set of qubits can be part of a quantum register supported by quantum hardware. As is described herein, the set of qubits can be {q₁, q₂, . . . q_{Q-1}, and q_{Q}} for example.

At block 1530, the computing system can execute, over the set of qubits, the second quantum circuit and the first quantum circuit after the second quantum circuit. Execution of the first and second quantum circuits in that other order yields a second result.

As is described herein, the order of block 1520 and block 1530 is not limited to that shown in FIG. 15. In some embodiments, the computing system can implement block 1520 and block 1530 in reverse order.

At block 1540, the computing system can generate, based on the first result and the second result, an attribute for a pair of circuits having the first quantum circuit and a second quantum circuit. The attribute designates the pair of circuits as one of tandem-executable or non-tandem-executable. In cases where the first result and second result are the same or otherwise indistinguishable, the attribute is generated to designate the pair of circuits as tandem-executable. In other cases where the first result and second results are different or distinguishable, the attribute is generated to designate the pair of circuits as non-tandem-executable.

At block 1550, the computing system can update a set of labeled pairs of quantum circuits to add a labeled pair of quantum circuits to the set. The labeled pair of quantum circuits includes the pair of circuits having the first quantum circuit and a second quantum circuit, and also includes the attribute.

Numerous example embodiments emerge from the foregoing detailed description and annexed drawings. Such example embodiments include the following:

Example 1. A computer-implemented method comprising: obtaining a production quantum circuit corresponding to a defined n-qubit computation, the production quantum circuit defined in a qubit register having one or more first qubits and executable in quantum hardware having multiple second qubits including the one or more first qubits; identifying a subset of the multiple second qubits that excludes the one or more first qubits; allocating at least one particular qubit of the subset for execution of a calibration quantum circuit; and causing the quantum hardware to execute the production quantum circuit and the calibration quantum circuit during a measurement cycle.

Example 2. The computer-implemented method of example 1, further comprising, determining that at least one particular qubit of the one or more first qubits is part of a non-entangling gate operation; and configuring the at least one particular qubit as being available for execution of a second calibration quantum circuit.

Example 3. The computer-implemented method of example 2, wherein execution of the production quantum circuit during the measurement cycle comprises performing one or more classical operations corresponding to one or more quantum mechanical operations associated with the at least one particular qubit.

Example 4. The computer-implemented method of example 3, further comprising adding a result of performing the one or more classical operations to a second result of performing one or more second quantum mechanical operations corresponding to the production quantum circuit.

Example 5. The computer-implemented method of example 1, further comprising, determining, during a next measurement cycle, that a particular qubit of the one or more first qubits exhibits a transition to an offline state; and allocating one or more second particular qubits for execution of a second calibration quantum circuit, the one or more second particular qubits pertaining to a set of qubits that includes the multiple second qubits less the particular qubit.

Example 6. The computer-implemented method of example 5, further comprising causing the quantum hardware to execute the second calibration quantum circuit during the next measurement cycle.

Example 7. A computer-implemented method comprising: obtaining a first quantum circuit; obtaining a second quantum circuit; determining that the first quantum circuit and the second quantum circuit are executable during a common measurement cycle in quantum hardware having multiple qubits; generating an executable quantum circuit by combining the first quantum circuit and the second quantum circuit; and causing the quantum hardware to execute the executable quantum circuit during the common measurement cycle.

Example 8. The computer-implemented method of example 7, wherein the determining comprises, determining that the first quantum circuit is defined in a first subset of the multiple qubits; and determining that the second quantum circuit is executable in at least one qubit in the complement of the first subset.

Example 9. The computer-implemented method of example 7, wherein the determining comprises, determining that the first quantum circuit is defined in a first subset of the multiple qubits; determining that at least one qubit in the first subset is part of a non-entangling gate operation; and determining that the second quantum circuit is executable in the at least one qubit.

Example 10. The computer-implemented method of example 7, wherein the determining comprises, causing the quantum hardware to execute the first quantum circuit, resulting in a first output state; causing the quantum hardware to execute the second quantum circuit, resulting in a second output state; causing the quantum hardware to execute the first quantum circuit and the second quantum circuit in a common measurement cycle, resulting in a third output state; causing the quantum hardware to execute the first quantum circuit and the second quantum circuit in a second common measurement cycle, resulting in a fourth output state; and determining that the first output state, the second output state, the third output state, and the fourth output state are equivalent.

Example 11. The computer-implemented method of example 7, wherein the first quantum circuit is a computation circuit, and wherein the second quantum circuit is a calibration circuit.

Example 12. The computer-implemented method of example 7, wherein the first quantum circuit is a computation circuit, and wherein the second quantum circuit is another computation circuit.

Example 13. The computer-implemented method of example 7, wherein the first quantum circuit is a calibration circuit, and wherein the second quantum circuit is another calibration circuit.

Example 14. A computing system comprising: at least one processor; and at least one memory devices storing processor-executable instructions that, in response to being executed by the at least one processor, individually or in combination, cause the computing system at least to: obtain a production quantum circuit corresponding to a defined n-qubit computation, the production quantum circuit defined in a qubit register having one or more first qubits and executable in quantum hardware having multiple second qubits including the one or more first qubits; identify a subset of the multiple second qubits that excludes the one or more first qubits; allocate at least one particular qubit of the subset for execution of a calibration quantum circuit; and cause the quantum hardware to execute the production quantum circuit and the calibration quantum circuit during a measurement cycle.

Example 15. The computing system of example 14, the at least one memory devices storing further processor-executable instructions that, in response to being executed by the at least one processor, individually or in combination, further cause the computing system to: determine that at least one particular qubit of the one or more first qubits is part of a non-entangling gate operation; and configure the at least one particular qubit as being available for execution of a second calibration quantum circuit.

Example 16. The computing system of example 15, wherein execution of the production quantum circuit during the measurement cycle comprises performing one or more classical operations corresponding to one or more quantum mechanical operations associated with the at least one particular qubit.

Example 17. The computing system of example 16, the at least one memory devices storing further processor-executable instructions that, in response to being executed by the at least one processor, individually or in combination, further cause the computing system to add a result of performing the one or more classical operations to a second result of performing one or more second quantum mechanical operations corresponding to the production quantum circuit.

Example 18. The computing system of example 14, the at least one memory devices storing further processor-executable instructions that, in response to being executed by the at least one processor, individually or in combination, further cause the computing system to: determine, during a next measurement cycle, that a particular qubit of the one or more first qubits exhibits a transition to an offline state; and allocate one or more second particular qubits for execution of a second calibration quantum circuit, the one or more second particular qubits pertaining to a set of qubits that includes the multiple second qubits less the particular qubit.

Example 19. The computing system of example 18, the at least one memory devices storing further processor-executable instructions that, in response to being executed by the at least one processor, individually or in combination, further cause the computing system to cause the quantum hardware to execute the second calibration quantum circuit during the next measurement cycle.

Example 20. A quantum information processing (QIP) system comprising: at least one processor; and at least one memory devices storing processor-executable instructions that, in response to being executed by the at least one processor, cause the QIP system at least to: obtain a production quantum circuit corresponding to a defined n-qubit computation, the production quantum circuit defined in a qubit register having one or more first qubits and executable in quantum hardware having multiple second qubits including the one or more first qubits; identify a subset of the multiple second qubits that excludes the one or more first qubits; allocate at least one particular qubit of the subset for execution of a calibration quantum circuit; and cause the quantum hardware to execute the production quantum circuit and the calibration quantum circuit during a measurement cycle.

Example 21. The QIP system of example 20, further comprising quantum hardware including multiple trapped-atom qubits individually addressable by a laser beam.

Example 22. A computer-implemented method for automatically identifying quantum circuits executable in tandem, the method comprising: testing, across a sampling of quantum circuit instances, validity of a hypothesis that execution of a pair of second quantum circuits yields a same result irrespective of order of execution of the pair of second quantum circuits; and generating, based on the testing, heuristics that identify a particular pair of quantum circuits as being executable in tandem.

Example 23. The computer-implemented method of example 22, further comprising: applying the heuristics to a first particular quantum circuit and a second particular quantum circuit; and determining, based on an outcome of the applying, that the first particular quantum circuit and the second particular quantum circuit are executable in tandem.

Example 24. The computer-implemented method of example 22, further comprising: obtaining a set of labeled pairs of quantum circuits, each labeled pair of the set of labeled pairs of quantum circuits comprises a first quantum circuit, a second quantum circuit, and a classification attribute designating the first quantum circuit and the second quantum circuit as one of tandem-executable or non-tandem-executable; and training, using the set of labeled pairs of quantum circuits, a machine-learning model to classify a non-labeled pair of quantum circuits as tandem-executable or non-tandem-executable.

Example 25. The computer-implemented method of example 24, further comprising: receiving first data defining a third quantum circuit; receiving second data defining a fourth quantum circuit; and determining a particular classification attribute by applying the trained machine-learning model to the first data and the second data, wherein the classification attribute designates the third quantum circuit and the fourth quantum circuit as tandem-executable or non-tandem-executable.

Example 26. The computer-implemented method of example 24, wherein the obtaining a set of labeled pairs of quantum circuits comprises: obtaining a set of particular quantum circuits; executing, over a set of qubits present in quantum hardware, a first quantum circuit of the particular circuits and a second quantum circuit of the particular quantum circuits after the first quantum circuit, yielding a first result; executing, over the set of qubits, the second quantum circuit and the first quantum circuit after the second quantum circuit, yielding a second result; generating, based on the first result and the second result, an attribute for a pair of circuits having the first quantum circuit and a second quantum circuit, wherein the attribute designates the pair of circuits as one of tandem-executable or non-tandem-executable; and updating the set of labeled pairs of quantum circuits to include the attribute and the pair of circuits having the first quantum circuit and a second quantum circuit.

Example 27. The computer-implemented method of example 26, wherein the set of particular quantum circuits comprises one or more of at least one random quantum circuit or at least one quantum circuit corresponding a defined class of algorithms.

Example 28. The computer-implemented method of example 27, wherein the defined class of algorithms is one of quantum machine learning, quantum simulation, or quantum chemistry.

Example 29. The computer-implemented method of example 26, wherein the first quantum circuit is a computation circuit, and wherein the second quantum circuit is a calibration circuit.

Example 30. The computer-implemented method of example 26, wherein the first quantum circuit is a computation circuit, and wherein the second quantum circuit is another computation circuit.

Example 31. The computer-implemented method of example 26, wherein the first quantum circuit is a calibration circuit, and wherein the second quantum circuit is another calibration circuit.

Example 32. A non-transitory computer readable medium containing processor-executable instructions that, in response to being executed by at least one processor, individually or in combination, cause a classical computing system to perform operations comprising: testing, across a sampling of quantum circuit instances, validity of a hypothesis that execution of a pair of second quantum circuits yields a same result irrespective of order of execution of the pair of second quantum circuits; and generating, based on the testing, heuristics that identify a particular pair of quantum circuits as being executable in tandem.

Example 33. The non-transitory computer readable medium of example 32, the operations further comprising: applying the heuristics to a first particular quantum circuit and a second particular quantum circuit; and determining, based on an outcome of the applying, that the first particular quantum circuit and the second particular quantum circuit are executable in tandem.

Example 34. The non-transitory computer readable medium of example 32, the operations further comprising: obtaining a set of labeled pairs of quantum circuits, each labeled pair of the set of labeled pairs of quantum circuits comprises a first quantum circuit, a second quantum circuit, and a classification attribute designating the first quantum circuit and the second quantum circuit as one of tandem-executable or non-tandem-executable; and training, using the set of labeled pairs of quantum circuits, a machine-learning model to classify a non-labeled pair of quantum circuits as tandem-executable or non-tandem-executable.

Example 35. The non-transitory computer readable medium of example 34, the operations further comprising: receiving first data defining a third quantum circuit; receiving second data defining a fourth quantum circuit; and determining a particular classification attribute by applying the trained machine-learning model to the first data and the second data, wherein the classification attribute designates the third quantum circuit and the fourth quantum circuit as tandem-executable or non-tandem-executable.

Example 36. The non-transitory computer readable medium of example 34, wherein the obtaining a set of labeled pairs of quantum circuits comprises: obtaining a set of particular quantum circuits; executing, over a set of qubits present in quantum hardware, a first quantum circuit of the particular circuits and a second quantum circuit of the particular quantum circuits after the first quantum circuit, yielding a first result; executing, over the set of qubits, the second quantum circuit and the first quantum circuit after the second quantum circuit, yielding a second result; generating, based on the first result and the second result, an attribute for a pair of circuits having the first quantum circuit and a second quantum circuit, wherein the attribute designates the pair of circuits as one of tandem-executable or non-tandem-executable; and updating the set of labeled pairs of quantum circuits to include the attribute and the pair of circuits having the first quantum circuit and a second quantum circuit.

Example 37. A classical computing system comprising: at least one processor; and at least one memory devices storing processor-executable instructions that, in response to being executed by the at least one processor, individually or in combination, cause the classical computing system at least to: test, across a sampling of quantum circuit instances, validity of a hypothesis that execution of a pair of second quantum circuits yields a same result irrespective of order of execution of the pair of second quantum circuits; and generate, based on the testing, heuristics that identify a particular pair of quantum circuits as being executable in tandem.

Example 38. The classical computing system of example 37, the at least one memory devices storing further processor-executable instructions that, in response to being executed by the at least one processor, individually or in combination, further cause the computing system to: apply the heuristics to a first particular quantum circuit and a second particular quantum circuit; and determine, based on an outcome of the applying, that the first particular quantum circuit and the second particular quantum circuit are executable in tandem.

Example 39. The classical computing system of example 37, the at least one memory devices storing further processor-executable instructions that, in response to being executed by the at least one processor, individually or in combination, further cause the computing system to: obtain a set of labeled pairs of quantum circuits, each labeled pair of the set of labeled pairs of quantum circuits comprises a first quantum circuit, a second quantum circuit, and a classification attribute designating the first quantum circuit and the second quantum circuit as one of tandem-executable or non-tandem-executable; and train, using the set of labeled pairs of quantum circuits, a machine-learning model to classify a non-labeled pair of quantum circuits as tandem-executable or non-tandem-executable.

Example 40. The non-transitory computer readable medium of example 39, the at least one memory devices storing further processor-executable instructions that, in response to being executed by the at least one processor, individually or in combination, further cause the computing system to: receive first data defining a third quantum circuit; receive second data defining a fourth quantum circuit; and determine a particular classification attribute by applying the trained machine-learning model to the first data and the second data, wherein the classification attribute designates the third quantum circuit and the fourth quantum circuit as tandem-executable or non-tandem-executable.

Example 41. A quantum information processing (QIP) system comprising: at least one processor; and at least one memory device storing processor-executable instructions that, in response to being executed by the at least one processor, cause the QIP system at least to: test, across a sampling of quantum circuit instances, validity of a hypothesis that execution of a pair of second quantum circuits yields a same result irrespective of order of execution of the pair of second quantum circuits; and generate, based on the testing, heuristics that identify a particular pair of quantum circuits as being executable in tandem.

Example 42. The QIP system of example 41, the at least one memory device storing further processor-executable instructions that, in response to being executed by the at least one processor, individually or in combination, further cause the QIP system to: apply the heuristics to a first particular quantum circuit and a second particular quantum circuit; and determine, based on an outcome of the applying, that the first particular quantum circuit and the second particular quantum circuit are executable in tandem.

Example 43. The QIP system of example 41, further comprising quantum hardware including multiple trapped-atom qubits individually addressable by a laser beam.

Example 44. A computer-implemented method for efficiently utilizing qubit resources to execute quantum circuits in a quantum hardware, the method comprising: determining that a first quantum circuit of the quantum circuits and a second quantum circuit of the quantum circuits are executable in tandem; combining the first quantum circuit and the second quantum circuit into a common quantum circuit for execution on the quantum hardware during a common measurement cycle; causing the quantum hardware to execute the first quantum circuit and the second quantum circuit in the common measurement cycle; and separating, upon or after termination of the common measurement cycle, a first result corresponding to execution of the first quantum circuit and a second result corresponding to execution of the second quantum circuit.

Example 45. The computer-implemented method of example 44, wherein the combining comprises: configuring the first quantum circuit to execute in a first subset of qubits in a qubit register formed in the quantum hardware; and configuring the second quantum circuit in a second subset of qubits in the qubit register, wherein second subset of qubits is the complement of the first subset of qubits.

Example 46. The computer-implemented method of example 45, wherein the separating comprises: analyzing a result from the first subset of qubits and the second subset of qubits; generating the first result by tracing the second subset of qubits out based on the analyzing; and generating the second result by tracing the first subset of qubits out based on the analyzing.

Example 47. The computer-implemented method of example 44, wherein the quantum circuits comprise at least one of computation circuit or a calibration circuit.

Example 48. The computer-implemented method of example 44, wherein the quantum circuits comprise multiple computation circuits.

Example 49. The computer-implemented method of example 44, wherein the quantum circuits comprise multiple calibration circuits.

Example 50. The computer-implemented method of example 44, further comprising compressing at least two quantum circuits of the quantum circuits into a single quantum circuit executable in tandem by remapping the at least two quantum circuits over the qubit resources.

Example 51. The computer-implemented method of example 44, further comprising: remapping a particular quantum circuit in multiple measurement cycles across a total number of qubits available in the quantum hardware, wherein the particular quantum circuit is remapped using a defined number of qubits that is less than the total number of qubits available in the quantum hardware.

Example 52. A non-transitory computer readable medium containing processor-executable instructions that, in response to being executed by at least one processor, individually or in combination, cause a computing system to perform operations comprising: determining that a first quantum circuit of the quantum circuits and a second quantum circuit of the quantum circuits are executable in tandem; combining the first quantum circuit and the second quantum circuit into a common quantum circuit for execution on the quantum hardware during a common measurement cycle; causing the quantum hardware to execute the first quantum circuit and the second quantum circuit in the common measurement cycle; and separating, upon or after termination of the common measurement cycle, a first result corresponding to execution of the first quantum circuit and a second result corresponding to execution of the second quantum circuit.

Example 53. The non-transitory computer readable medium of example 52, wherein the combining comprises: configuring the first quantum circuit to execute in a first subset of qubits in a qubit register formed in the quantum hardware; and configuring the second quantum circuit in a second subset of qubits in the qubit register, wherein second subset of qubits is the complement of the first subset of qubits.

Example 54. The non-transitory computer readable medium of example 53, wherein the separating comprises: analyzing a result from the first subset of qubits and the second subset of qubits; generating the first result by tracing the second subset of qubits out based on the analyzing; and generating the second result by tracing the first subset of qubits out based on the analyzing.

Example 55. The non-transitory computer readable medium of example 52, further comprising compressing at least two quantum circuits of the quantum circuits into a single quantum circuit executable in tandem by remapping the at least two quantum circuits over the qubit resources.

Example 56. The computer-implemented method of example 52, further comprising: remapping a particular quantum circuit in multiple measurement cycles across a total number of qubits available in the quantum hardware, wherein the particular quantum circuit is remapped using a defined number of qubits that is less than the total number of qubits available in the quantum hardware.

Example 57. A classical computing system comprising: at least one processor; and at least one memory devices storing processor-executable instructions that, in response to being executed by the at least one processor, individually or in combination, cause the classical computing system at least to: determine that a first quantum circuit of the quantum circuits and a second quantum circuit of the quantum circuits are executable in tandem; combine the first quantum circuit and the second quantum circuit into a common quantum circuit for execution on the quantum hardware during a common measurement cycle; cause the quantum hardware to execute the first quantum circuit and the second quantum circuit in the common measurement cycle; and separate, upon or after termination of the common measurement cycle, a first result corresponding to execution of the first quantum circuit and a second result corresponding to execution of the second quantum circuit.

Example 58. The classical computing system of example 57, combining the first quantum circuit and the second quantum circuit into a common quantum circuit for execution on the quantum hardware during a common measurement cycle comprises: configuring the first quantum circuit to execute in a first subset of qubits in a qubit register formed in the quantum hardware; and configuring the second quantum circuit in a second subset of qubits in the qubit register, wherein second subset of qubits is the complement of the first subset of qubits.

Example 59. The classical computing system of example 58, wherein separating, upon or after termination of the common measurement cycle, a first result corresponding to execution of the first quantum circuit and a second result corresponding to execution of the second quantum circuit comprises: analyzing a result from the first subset of qubits and the second subset of qubits; generating the first result by tracing the second subset of qubits out based on the analyzing; and generating the second result by tracing the first subset of qubits out based on the analyzing.

Example 60. The classical computing system of example 57, further comprising compressing at least two quantum circuits of the quantum circuits into a single quantum circuit executable in tandem by remapping the at least two quantum circuits over the qubit resources.

Example 61. The classical computing system of example 57, further comprising: remapping a particular quantum circuit in multiple measurement cycles across a total number of qubits available in the quantum hardware, wherein the particular quantum circuit is remapped using a defined number of qubits that is less than the total number of qubits available in the quantum hardware.

Example 62. A quantum information processing (QIP) system comprising: at least one processor; and at least one memory devices storing processor-executable instructions that, in response to being executed by the at least one processor, cause the QIP system at least to: determine that a first quantum circuit of the quantum circuits and a second quantum circuit of the quantum circuits are executable in tandem; combine the first quantum circuit and the second quantum circuit into a common quantum circuit for execution on the quantum hardware during a common measurement cycle; cause the quantum hardware to execute the first quantum circuit and the second quantum circuit in the common measurement cycle; and separate, upon or after termination of the common measurement cycle, a first result corresponding to execution of the first quantum circuit and a second result corresponding to execution of the second quantum circuit.

Example 63. The QIP system of example 62, further comprising quantum hardware including multiple trapped-atom qubits individually addressable by a laser beam.

Various aspects of the disclosure may take the form of an entirely or partially hardware aspect, an entirely or partially software aspect, or a combination of software and hardware. Furthermore, as described herein, various aspects of the disclosure (e.g., systems and methods) may take the form of a computer program product comprising a computer-readable non-transitory storage medium having computer-accessible instructions (e.g., computer-readable and/or computer-executable instructions) such as computer software, encoded or otherwise embodied in such storage medium. Those instructions can be read or otherwise accessed and executed by one or more processors to perform or permit the performance of the operations described herein. The instructions can be provided in any suitable form, such as source code, compiled code, interpreted code, executable code, static code, dynamic code, assembler code, combinations of the foregoing, and the like. Any suitable computer-readable non-transitory storage medium may be utilized to form the computer program product. For instance, the computer-readable medium may include any tangible non-transitory medium for storing information in a form readable or otherwise accessible by one or more computers or processor(s) functionally coupled thereto. Non-transitory storage media can include read-only memory (ROM); random access memory (RAM); magnetic disk storage media; optical storage media; flash memory, and so forth.

Aspects of this disclosure are described herein with reference to block diagrams and flowchart illustrations of methods, systems, apparatuses, and computer program products. It can be understood that each block of the block diagrams and flowchart illustrations, and combinations of blocks in the block diagrams and flowchart illustrations, respectively, can be implemented by computer-accessible instructions. In certain implementations, the computer-accessible instructions may be loaded or otherwise incorporated into a general-purpose computer, a special-purpose computer, or another programmable information processing apparatus to produce a particular machine, such that the operations or functions specified in the flowchart block or blocks can be implemented in response to execution at the computer or processing apparatus.

Unless otherwise expressly stated, it is in no way intended that any protocol, procedure, process, or method set forth herein be construed as requiring that its acts or steps be performed in a specific order. Accordingly, where a process or method claim does not actually recite an order to be followed by its acts or steps, or it is not otherwise specifically recited in the claims or descriptions of the subject disclosure that the steps are to be limited to a specific order, it is in no way intended that an order be inferred, in any respect. This holds for any possible non-express basis for interpretation, including: matters of logic with respect to the arrangement of steps or operational flow; plain meaning derived from grammatical organization or punctuation; the number or type of aspects described in the specification or annexed drawings; or the like.

As used in this disclosure, including the annexed drawings, the terms “component,” “module,” “system,” and the like are intended to refer to a computer-related entity or an entity related to an apparatus with one or more specific functionalities. The entity can be either hardware, a combination of hardware and software, software, or software in execution. One or more of such entities are also referred to as “functional elements.” As an example, a component can be a process running on a processor, a processor, an object, an executable, a thread of execution, a program, and/or a computer. For example, both an application running on a server or network controller, and the server or network controller can be a component. One or more components can reside within a process and/or thread of execution and a component can be localized on one computer and/or distributed between two or more computers. Also, these components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which parts can be controlled or otherwise operated by program code executed by a processor. As yet another example, a component can be an apparatus that provides specific functionality through electronic components without mechanical parts, the electronic components can include a processor to execute program code that provides, at least partially, the functionality of the electronic components. As still another example, interface(s) can include I/O components or Application Programming Interface (API) components. While the foregoing examples are directed to aspects of a component, the exemplified aspects or features also apply to a system, module, and similar.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in this specification and annexed drawings should be construed to mean “one or more” unless specified otherwise or clear from context to be directed to a singular form.

In addition, the terms “example” and “such as” are utilized herein to mean serving as an instance or illustration. Any aspect or design described herein as an “example” or referred to in connection with a “such as” clause is not necessarily to be construed as preferred or advantageous over other aspects or designs described herein. Rather, use of the terms “example” or “such as” is intended to present concepts in a concrete fashion. The terms “first,” “second,” “third,” and so forth, as used in the claims and description, unless otherwise clear by context, is for clarity only and doesn't necessarily indicate or imply any order in time or space.

The term “processor,” as utilized in this disclosure, can refer to any computing processing unit or device comprising processing circuitry that can operate on data and/or signaling. A computing processing unit or device can include, for example, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can include an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. In some cases, processors can exploit nano-scale architectures, such as molecular and quantum-dot based transistors, switches and gates, in order to optimize space usage or enhance performance of user equipment. A processor may also be implemented as a combination of computing processing units.

In addition, terms such as “store,” “data store,” data storage,” “database,” and substantially any other information storage component relevant to operation and functionality of a component, refer to “memory components,” or entities embodied in a “memory” or components comprising the memory. It will be appreciated that the memory components described herein can be either volatile memory or nonvolatile memory, or can include both volatile and nonvolatile memory. Moreover, a memory component can be removable or affixed to a functional element (e.g., device, server).

Simply as an illustration, nonvolatile memory can include read only memory (ROM), programmable ROM (PROM), electrically programmable ROM (EPROM), electrically erasable ROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Additionally, the disclosed memory components of systems or methods herein are intended to comprise, without being limited to comprising, these and any other suitable types of memory.

Various aspects described herein can be implemented as a method, apparatus, or article of manufacture using standard programming and/or engineering techniques. In addition, various of the aspects disclosed herein also can be implemented by means of program modules or other types of computer program instructions stored in a memory device and executed by a processor, or other combination of hardware and software, or hardware and firmware. Such program modules or computer program instructions can be loaded onto a general-purpose computer, a special-purpose computer, or another type of programmable data processing apparatus to produce a machine, such that the instructions which execute on the computer or other programmable data processing apparatus create a means for implementing the functionality of disclosed herein.

The term “article of manufacture” as used herein is intended to encompass a computer program accessible from any computer-readable device, carrier, or media. For example, computer readable media can include but are not limited to magnetic storage devices (e.g., hard drive disk, floppy disk, magnetic strips, or similar), optical discs (e.g., compact disc (CD), digital versatile disc (DVD), blu-ray disc (BD), or similar), smart cards, and flash memory devices (e.g., card, stick, key drive, or similar).

The detailed description set forth herein in connection with the annexed figures is intended as a description of various configurations or implementations and is not intended to represent the only configurations or implementations in which the concepts described herein may be practiced. The detailed description includes specific details for the purpose of providing a thorough understanding of various concepts. However, it will be apparent to those skilled in the art that these concepts may be practiced without these specific details or with variations of these specific details. In some instances, well-known components are shown in block diagram form, while some blocks may be representative of one or more well-known components.

The previous description of the disclosure is provided to enable a person skilled in the art to make or use the disclosure. Various modifications to the disclosure will be readily apparent to those skilled in the art, and the common principles defined herein may be applied to other variations without departing from the scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A computer-implemented method comprising:
obtaining a production quantum circuit corresponding to a defined n-qubit computation, the production quantum circuit defined in a qubit register having one or more first qubits and executable in quantum hardware having multiple second qubits including the one or more first qubits;
identifying a subset of the multiple second qubits that excludes the one or more first qubits;
allocating at least one particular qubit of the subset for execution of a calibration quantum circuit; and
causing the quantum hardware to execute the production quantum circuit and the calibration quantum circuit during a measurement cycle.

2. The computer-implemented method of claim 1, further comprising,
determining that at least one particular qubit of the one or more first qubits is part of a non-entangling gate operation; and
configuring the at least one particular qubit as being available for execution of a second calibration quantum circuit.

3. The computer-implemented method of claim 2, wherein execution of the production quantum circuit during the measurement cycle comprises performing one or more classical operations corresponding to one or more quantum mechanical operations associated with the at least one particular qubit.

4. The computer-implemented method of claim 3, further comprising adding a result of performing the one or more classical operations to a second result of performing one or more second quantum mechanical operations corresponding to the production quantum circuit.

5. The computer-implemented method of claim 1, further comprising,
determining, during a next measurement cycle, that a particular qubit of the one or more first qubits exhibits a transition to an offline state; and
allocating one or more second particular qubits for execution of a second calibration quantum circuit, the one or more second particular qubits pertaining to a set of qubits that includes the multiple second qubits less the particular qubit.

6. The computer-implemented method of claim 5, further comprising causing the quantum hardware to execute the second calibration quantum circuit during the next measurement cycle.

7. A computer-implemented method comprising:
obtaining a first quantum circuit;
obtaining a second quantum circuit;
determining that the first quantum circuit and the second quantum circuit are executable during a common measurement cycle in quantum hardware having multiple qubits;
generating an executable quantum circuit by combining the first quantum circuit and the second quantum circuit; and
causing the quantum hardware to execute the executable quantum circuit during the common measurement cycle.

8. The computer-implemented method of claim 7, wherein the determining comprises, determining that the first quantum circuit is defined in a first subset of the multiple qubits; and
determining that the second quantum circuit is executable in at least one qubit in the complement of the first subset.

9. The computer-implemented method of claim 7, wherein the determining comprises,
determining that the first quantum circuit is defined in a first subset of the multiple qubits;
determining that at least one qubit in the first subset is part of a non-entangling gate operation; and
determining that the second quantum circuit is executable in the at least one qubit.

10. The computer-implemented method of claim 7, wherein the determining comprises,
causing the quantum hardware to execute the first quantum circuit, resulting in a first output state;
causing the quantum hardware to execute the second quantum circuit, resulting in a second output state;
causing the quantum hardware to execute the first quantum circuit and the second quantum circuit in a common measurement cycle, resulting in a third output state;
causing the quantum hardware to execute the first quantum circuit and the second quantum circuit in a second common measurement cycle, resulting in a fourth output state; and
determining that the first output state, the second output state, the third output state, and the fourth output state are equivalent.

11. The computer-implemented method of claim 7, wherein the first quantum circuit is a computation circuit, and wherein the second quantum circuit is a calibration circuit.

12. The computer-implemented method of claim 7, wherein the first quantum circuit is a computation circuit, and wherein the second quantum circuit is another computation circuit.

13. The computer-implemented method of claim 7, wherein the first quantum circuit is a calibration circuit, and wherein the second quantum circuit is another calibration circuit.

14. A computing system comprising:
at least one processor; and
at least one memory devices storing processor-executable instructions that, in response to being executed by the at least one processor, individually or in combination, cause the computing system at least to:
obtain a production quantum circuit corresponding to a defined n-qubit computation, the production quantum circuit defined in a qubit register having one or more first qubits and executable in quantum hardware having multiple second qubits including the one or more first qubits;
identify a subset of the multiple second qubits that excludes the one or more first qubits;
allocate at least one particular qubit of the subset for execution of a calibration quantum circuit; and
cause the quantum hardware to execute the production quantum circuit and the calibration quantum circuit during a measurement cycle.

15. The computing system of claim 14, the at least one memory devices storing further processor-executable instructions that, in response to being executed by the at least one processor, individually or in combination, further cause the computing system to:
determine that at least one particular qubit of the one or more first qubits is part of a non-entangling gate operation; and
configure the at least one particular qubit as being available for execution of a second calibration quantum circuit.

16. The computing system of claim 15, wherein execution of the production quantum circuit during the measurement cycle comprises performing one or more classical operations corresponding to one or more quantum mechanical operations associated with the at least one particular qubit.

17. The computing system of claim 16, the at least one memory devices storing further processor-executable instructions that, in response to being executed by the at least one processor, individually or in combination, further cause the computing system to add a result of performing the one or more classical operations to a second result of performing one or more second quantum mechanical operations corresponding to the production quantum circuit.

18. The computing system of claim 14, the at least one memory devices storing further processor-executable instructions that, in response to being executed by the at least one processor, individually or in combination, further cause the computing system to:
determine, during a next measurement cycle, that a particular qubit of the one or more first qubits exhibits a transition to an offline state; and
allocate one or more second particular qubits for execution of a second calibration quantum circuit, the one or more second particular qubits pertaining to a set of qubits that includes the multiple second qubits less the particular qubit.

19. The computing system of claim 18, the at least one memory devices storing further processor-executable instructions that, in response to being executed by the at least one processor, individually or in combination, further cause the computing system to cause the quantum hardware to execute the second calibration quantum circuit during the next measurement cycle.

20. A quantum information processing (QIP) system comprising:
at least one processor; and
at least one memory devices storing processor-executable instructions that, in response to being executed by the at least one processor, cause the QIP system at least to:
obtain a production quantum circuit corresponding to a defined n-qubit computation, the production quantum circuit defined in a qubit register having one or more first qubits and executable in quantum hardware having multiple second qubits including the one or more first qubits;
identify a subset of the multiple second qubits that excludes the one or more first qubits;
allocate at least one particular qubit of the subset for execution of a calibration quantum circuit; and
cause the quantum hardware to execute the production quantum circuit and the calibration quantum circuit during a measurement cycle.

21. The QIP system of claim 20, further comprising quantum hardware including multiple trapped-atom qubits individually addressable by a laser beam.
